(19) United States
(12) Patent Application Publication
(10) Pub. No.: US 2013/0340830 A1
(43) Pub. Date: Dec. 26, 2013

(54) SOLAR CELL BACKSHEET, PRODUCING METHOD OF THE SAME, AND SOLAR CELL MODULE

(71) Applicant: FUJIFILM Corporation, Tokyo (JP)

(72) Inventors: Yohei ARITOSHI, Kanagawa (JP); Akira HATAKEYAMA, Kanagawa (JP)

(73) Assignee: FUJIFILM Corporation, Tokyo (JP)

(21) Appl. No.: 14/018,933

(22) Filed: Sep. 5, 2013

Related U.S. Application Data
(63) Continuation of application No. PCT/JP2012/055282, filed on Mar. 1, 2012.

(30) Foreign Application Priority Data
Mar. 25, 2011 (JP) 2011-068809

(51) Int. Cl. H01L 31/048; H01L 31/18

(52) U.S. Cl. CPC H01L 31/0487; H01L 31/18
USPC 136/259; 136/252; 428/422; 427/74; 427/535

(57) ABSTRACT

A solar cell backsheet, which is arranged in contact with a sealing material of a cell-side substrate on which a photovoltaic element is sealed with the sealing material, the solar cell backsheet including a polyester film base material and at least one polymer layer arranged thereon, wherein the polyester film base material has a carboxyl group content of from 1 eq/ton to 15 eq/ton, a minute endothermic peak temperature Tmeta (° C.) of 220° C. or lower as determined by differential scanning calorimetry, and an average elongation retention ratio of 10% or more as determined after being left to stand for 72 hours under conditions of a temperature of 125° C. and a relative humidity of 100% RH; and the at least one polymer layer comprises at least a fluorocarbon-based polymer, has a crosslinked structure derived from at least one crosslinking agent selected from carbodiimide-based compounds and oxazoline-based compounds and is formed by coating.

### CROSS-REFERENCE TO RELATED APPLICATION

This application is a continuation, application of, and claims priority from, International Application No. PCT/XP/2012/055282, filed Mar. 1, 2012, which is incorporated herein by reference. Further, this application claims priority from Japanese Patent Application No. 2011-068809, filed Mar. 25, 2011, which is incorporated herein by reference.

### BACKGROUND OF THE INVENTION

1. Technical Field

The present invention relates to a backsheet for a solar cell, which is disposed on an opposite side from a sunlight incident side of a solar cell element, to a method of producing the same, and to a solar cell module.

2. Background Art

Solar cells are power generating systems that do not discharge carbon dioxide during power generation and have little adverse effect on the environment, and in recent years, solar cells have been rapidly popularized.

A solar cell module generally has a structure in which solar cells are sandwiched between glass on a sunlight incident side and a so-called backsheet that is placed on the opposite side (rear side) from the sunlight incident side. A space between the glass and the solar cells and a space between the solar cells and the backsheet are respectively sealed with an EVA (ethylene-vinylacetate) resin or the like.

A solar cell power generation module is required to have excellent weather-resistance performance with respect to the natural environment so that battery performance in terms, for example, of power generation efficiency can be maintained over a long period of several decades even in a harsh service environment where the solar cell power generation module is exposed to the elements and direct sunlight. In order to impart a solar cell power generation module with this kind of durability, it is required that the materials constituting the solar cell power generation module, such as a backsheet and a sealing material which seals an element, have weather-resistance.

A backsheet has a function of inhibiting moisture intrusion from the back surface of a solar cell module. Conventionally, glass, a fluorine-containing resin and the like have been used for a backsheet; however, in recent years, polyester films are more increasingly used in view of costs. This kind of backsheet is not merely a polymer sheet and may be imparted with a variety of functions.

As polyester films applied as a backsheet, polyethylene terephthalate (hereinafter, also referred to as “PET”) films have been used, in particular, and various technologies for improving their weather resistance have been proposed. For example, in Japanese Patent Application Laid-Open (JP-A) No. 2010-248492, a PET film in which at least three constituent components are made to coexist in a polyester is disclosed. Further, in WO 2010/110119, a PET film is disclosed in which the terminal carboxyl group concentration and the minor endothermic peak temperature Tmeta (° C.) determined by differential scanning calorimetry (DSC) are both controlled to within specific ranges so as to improve hydrolysis resistance.

Meanwhile, when a common PET film is used for a prolonged period of time as a solar cell protection sheet, particularly as a solar cell backsheet serving as an outermost layer, there are problems in that the PET film is easily detached from the solar cell and that the strength of the PET film itself is likely to deteriorate. Moreover, a backsheet composed of a single PET film layer is likely to be detached from a sealing material such as EVA when placed in an outdoor environment or the like where the backsheet is exposed to the elements. Therefore, in order to overcome these problems of weather resistance, conventionally, laminate-type backsheets in which a weather-resistant film is pasted onto the outermost layer of a base material film made of a PET or the like have been mainly used. Among such pasted-type laminates, fluorine-based polymer films such as polyvinyl fluoride films have been most commonly used. Examples of a solar cell backsheet utilizing a fluorine-based polymer film include a laminate composed of a composite film of a fluorine-based polymer film and a metal foil, a fluorine-based polymer film, a silicon oxide thin film layer and a transparent resin (see, for example, JP-A No. H4-239634).

However, in cases where a fluorine-based polymer film is used as a laminate-type solar cell backsheet, there is a problem in that the interlayer adhesion (cohesiveness) between a PET film and the fluorine-based polymer film is weak and detachment is thus likely to occur between the layers particularly when the backsheet is used for a prolonged period of time. As technologies that solve this kind of problem in the use of a fluorine-based polymer film, coating-type backsheets in which a composition containing a fluorine-based polymer is coated onto a PET base material film have been recently developed (see JP-A No. 2007-35694, WO 2008/143719 and JP-A No. 2010-053317). For example, JP-A No. 2007-35694 and WO 2008/143719 disclose a solar cell backsheet in which a cured coating film of a fluorine-based polymer coating material containing a curable functional group is directly formed on a polyester film and a sheet in which a fluorine-based polymer solution containing a conventionally known crosslinking agent and a curing agent is coated on a substrate. Meanwhile, as exemplary cases where a PET base material is subjected to a surface treatment as an alternative to the use of a crosslinking agent, the examples of JP-A No. 2010-053317 disclose sheets prepared by performing a corona surface treatment on a PET base material and then coating thereon a fluorine-based polymer.

As such surface treatment technology used in combination with a fluorine-based polymer, in addition to the corona treatment, flame treatment and glow discharge treatment that are described in JP-A No. 2010-053317, a method of irradiating a fluorine-based polymer with a special electromagnetic wave and a plasma treatment are described in JP-A No. 2002-282777. In the examples of JP-A No. 2002-282777, a method of irradiating a fluorine-based polymer with a special electromagnetic wave, particularly in near-vacuum low-pressure conditions, and an aspect of performing a plasma treatment are disclosed.

### SUMMARY OF THE INVENTION

### Technical Problem

However, in cases where such polyester films as disclosed in JP-A No. 2010-248492 and WO 2010/110119 are employed as a base material in a solar cell backsheet, there is still a problem of detachment of the backsheet when exposed to moisture and heat over time. Further, in cases where the methods disclosed in JP-A No. H4-239634, JP-A No. 2007-35694, WO 2008/143739, JP-A No. 2010-053317 and JP-A No. 2002-282777 are used, a sufficient improvement effect cannot be attained at present.

The present invention has been made in view of the above-described circumstances and an object of the present invention is to provide a solar cell backsheet having excellent adhesion durability over time in moisture and heat; a production method thereof; and a solar cell module exhibiting stable power generation efficiency. The problem to be solved by the present invention is to achieve the above-described object

### Solution to Problem

<1> A solar cell backsheet, which is arranged in contact with a sealing material of a cell-side substrate on which a photovoltaic element is sealed with the sealing material, the solar cell backsheet including a polyester film base material and at least one polymer layer arranged thereon, wherein the polyester film base material has a carboxyl group content of from 1 eq/ton to 15 eq/ton, a minute endothermic peak temperature Tmeta (° C.) of 220° C. or lower as determined by differential scanning calorimetry, and an average elongation retention ratio of 10% or more as determined after being left to stand for 72 hours under conditions of a temperature of 125° C. and a relative humidity of 100% RH; and the at least one polymer layer includes at least a fluorocarbon-based polymer, has a crosslinked structure derived from at least one crosslinking agent selected from the group consisting of carbodiimide-based compounds and oxazoline-based compounds, and is formed by coating.

<2> The solar cell backsheet according to the item <1>, wherein the polyester film base material includes a polyester containing a constituent component of dicarboxylic acid, a constituent component of a diol and a constituent component (p) in which a sum of a number of carboxyl groups (a) and a number of hydroxy 1 groups (b) (a+b) is 3 or greater, and a content of the constituent component (p) is in a range of from 0.005% by mole to 2.5% by mole with respect to a total amount of constituent components contained in the polyester.

<3> The solar cell backsheet according to the item <1> or the item <2>, wherein the polyester film base material includes a buffer agent in a range of from 0.1 mol/ton to 5.0 mol/ton with respect to a total mass of the polyester contained in the polyester film base material.

<4> The solar cell backsheet according to any one of the items <1> to <3>, wherein the polyester film base material comprises a terminal blocking agent, which is a carbodiimide compound, in a range of from 0.1% by mass to 5% by mass with respect to a total mass of the polyester contained in the polyester film base material.

<5> The solar cell backsheet according to any one of the items <1> to <4>, wherein a content of phosphorus atoms determined by a fluorescent X-ray analysis of the polyester film base material is 200 ppm or greater.

<6> The solar cell backsheet according to any one of the items <1> to <5>, wherein the polyester film base material is subjected to a surface treatment.

<7> The solar cell backsheet according to the item <6>, wherein the surface treatment is at least one surface treatment selected from the group consisting of a flame treatment in which flame is applied together with a silane compound and atmospheric pressure plasma treatment.

<8> The solar cell backsheet according to the item <6> or the item <7>, wherein the at least one polymer layer including at least a fluorocarbon-based polymer and a crosslinked structure derived from at least one crosslinking agent selected from the group consisting of carbodiimide-based compounds and oxazoline-based compounds, directly contacts a surface of the polyester film base material subjected to a surface treatment.

<9> The solar cell backsheet according to any one of the items <1> to <8>, wherein the at least one polymer layer including at least a fluorocarbon-based polymer and a crosslinked structure derived from at least one crosslinking agent selected from the group consisting of carbodiimide-based compounds and oxazoline-based compounds is an outermost layer.

<10> The solar cell backsheet according to any one of the items <1> to <9>, wherein the at least one polymer layer is a reflective layer that reflects light and comprises a white pigment.

<11> A method of forming a solar cell backsheet, the method including: applying a coating liquid including at least a fluorocarbon-based polymer and at least one crosslinking agent selected from the group consisting of carbodiimide-based compounds and oxazoline-based compounds, onto a polyester film base material having a carboxyl group content of from 1 eq/ton to 15 eq/ton, a minute endothermic peak temperature Tmeta (° C.) of 220° C. or lower as determined by differential scanning calorimetry, and an average elongation retention ratio of 10% or more as determined after being left to stand for 72 hours under conditions of a temperature of 125° C. and a relative humidity of 100% RH.

<12> The method of forming a solar cell backsheet according to the item <11>, the method further including: applying, onto a surface side of the polyester film base material that is coated with the coating liquid, at least one surface treatment selected from the group consisting of a flame treatment in which flame is applied together with a silane compound and atmospheric pressure plasma treatment.

<13> The method of forming a solar cell backsheet according to the item <11> or the item <12>, wherein the coating liquid further includes a solvent, and 50% by mass or greater of the solvent is water.

<14> A solar cell module comprising the solar cell backsheet according to any one of the items <1> to <5>, or the solar cell backsheet formed by the method of forming a solar cell backsheet according to any one of the items <11> to <13>.

<15> The solar cell module according to the item <14>, further including: a transparent front base board through which sunlight enters; a cell structural portion that is provided on the front base board and includes a solar cell element and a sealing material that seals the solar cell element; and at least one solar cell backsheet according to any one of the items <1> to <5>, or at least one solar cell backsheet formed by the method of forming a solar cell backsheet according to any one of the items <11> to <13>, the solar cell backsheet being provided on a side of the cell structural portion opposite to a side at which the front base board is placed, so as to be adjacent to the sealing material. [Advantageous Effects of Invention]

According to the present invention, a solar cell backsheet having excellent adhesion durability after a lapse time under moisture and heat a production method thereof, and a solar cell module exhibiting a stable power generation efficiency can be provided.

### DESCRIPTION OF EMBODIMENTS

### Mode for Carrying Out the Invention

The solar cell backsheet according to the present invention and the production method thereof as well as the solar cell module according to the present invention will now be describe in detail.

[Solar Cell Backsheet and Production Method Thereof]

The solar cell backsheet according to the present invention is a solar cell backsheet arranged in contact with a sealing material of a cell-side substrate on which a photovoltaic element is sealed with the above-described sealing material, the solar cell backsheet including a polyester film base material and at least one polymer layer arranged thereon, wherein the above-described polyester film base material has a terminal carboxyl group concentration of from 1 eq/ton to 15 eq/ton, a minor endothermic peak temperature Tmeta PC) determined by differential scanning calorimetry of not higher than 220° C., and an average elongation retention ratio, which is determined after being left to stand for 72 hours at a temperature of 125° C. and a relative humidity (RH) of 100%, of not lower than 10%; and the above-described at least one polymer layer contains at least a fluorine-based polymer (hereinafter, also referred to as “fluorocarbon-based polymer”), has a crosslinked structure derived from at least one crosslinking agent selected from carbodiimide-based compounds and oxazoline-based compounds and is formed by coating.

The backsheet according to the present invention is required to contain at least, as its constituent components, a polymer film base material which has a terminal carboxyl group concentration, a minor endothermic peak temperature Tmeta (° C.) determined by differential scanning calorimetry and an average elongation retention ratio, which is determined after being left to stand for 72 hours at a temperature of 125° C. and a relative humidity (RH) of 100%, all in specific ranges; and a polymer layer which contains at least a fluorine-based polymer and has a crosslinked structure derived from at least one crosslinking agent selected from carbodiimide-based compounds and oxazoline-based compounds. By this constitution, the backsheet according to the present invention attains excellent durability of adhesion with an adjacent member(s) after a lapse time under moisture and heat. Accordingly, the backsheet according to the present invention can exhibit excellent durability over a prolonged period of time in an environment where the backsheet is exposed to heat and moisture for an extended period.

Further, a solar cell module having the above-described backsheet of the present invention can attain good power generation performance and stably maintain power generation efficiency over a prolonged period of time.

(Polyester Film Base Material)

The polyester film base material in the invention is preferably a base material formed from a polyester film which has a terminal carboxyl group concentration of from 1 eq/ton to 15 eq/ton; a minor endothermic peak temperature Tmeta (° C.) of 220° C. or lower as determined by differential scanning calorimetry (DSC); and an average elongation retention rate obtainable after storage for 72 hours under the conditions of a temperature of 125° C. and relative moisture of 100% RH, of 10% or greater.

Hereinafter, the polyester film that constitutes the polyester film base material will be described in detail.

<Terminal Carboxyl Group Concentration (AV)>

The terminal carboxyl group concentration (hereinafter, appropriately referred to as “AV”) in the polyester film is from 1 eq/ton to 15 eq/ton, more preferably from 2 eq/ton to 13 eq/ton, and even more preferably from 3 eq/ton to 9 eq/ton. In this regard, “equivalent/ton (eq/ton)” represents a mole equivalent per one ton in this specification.

A terminal carboxyl group has a function of forming a hydrogen bond with a hydroxyl group existing on the surface of a member or layer adjacent to the polyester film and thereby improving the adhesive force. Further, in the present invention, by forming the polymer layer using a crosslinking agent which reacts with the carboxyl groups existing in the polyester film which is a base material (particularly the carboxyl groups existing on the film surface) to form strong primary bonds, an unprecedentedly high adhesive force-imparting function is attained. Therefore, when the AV is less than 1 eq/ton, the adhesive force is reduced. Meanwhile, H⁺ in the terminal carboxy group acts as an acid catalyst to hydrolyze polyester molecules. Therefore, with the AV being higher than 15 eq/ton, when the polyester film is left in a high-humidity condition for a certain period of time, the molecular weight and the mechanical strength of the polyester film surface are reduced due to hydrolysis and, as a result, fee backsheet is detached (adhesion failure) due to damage sustained to the polyester film surface.

Examples of a method for specific adjustment of the AV include adjustment of the “plane orientation coefficient” of the polyester film, adjustment of the types and contents of the “constituent components” that constitute the polyester, addition of additives such as a “buffering agent” or a “terminal blocking agent”, and adjustment of the “amount of phosphorus atoms” present in the polyester.

When the AV is adjusted to the range of from 1 eq/ton to 15 eq/ton by those specific methods for adjustment, peeling (adhesion failure) of the back sheet due to the hydrolysis of the polyester that is attributable to the terminal carboxyl groups may be suitably suppressed.

Here, among the specific methods for adjustment, when it is intended to adjust the AV to fall in the range of the invention by means of the amount of addition of additives such as a “buffering agent” and a “terminal blocking agent”, and/or the “amount of phosphorus atoms”, it is necessary to increase these contents in the polyester. However, inclusion of an excess amount of additives or phosphorus atoms in a polyester film brings about problems such as precipitation of additives and the like at a surface of the base material in case where the base material is kept for a certain period of time under a hot and moisture, or an enhancement of thermal shrinkage due to excessively strong orientation, and eventually causes peeling (adhesion failure) of back sheets. From such viewpoints, it is necessary that the AV of the polyester film according to the invention be from 1 eq/ton to 15 eq/ton.

In regard to the polyester raw material (pellet) provided for the formation of a polyester film, it is preferable to adjust the terminal carboxyl group concentration (AV) to the range of 15 mol/ton or less, in order to enhance the hydrolysis resistance. The terminal carboxyl group concentration is preferably 13 mol/ton or less, more preferably 10 mol/ton or less, and most preferably 8 mol/ton or less. The lower limit is not particularly limited, but 0 mol/ton would be the theoretical lower limit. The AV of pellets may be adjusted by the polymerization conditions, the solid state polymerization conditions, and the terminal blocking agent.

A specific method for the measurement of AV will be described below.

<Minor Endothermic Peak Temperature Tmeta (° C.) Determined by Differential Scanning Calorimetry>

A polyester film in the invention is such that the minor endothermic peak temperature Tmeta (° C.) as determined by a differential scanning calorimetry (hereinafter, also referred to as “DSC”) is 220° C. or lower, preferably from 150° C. to 215° C., and more preferably from 160° C. to 210° C.

The minor endothermic peak temperature Tmeta (° C.) may be adjusted to the range related to the invention by controlling the “plane orientation coefficient” in the polyester film, and the “temperature of the heat fixing carried out after stretching” at the time of forming the polyester film. The temperature of the heat fixing carried out after stretching is preferably from 150° C. to 220° C., more preferably from 160° C. to 210° C., and even more preferably 170° C. to 200° C.

A specific method for the measurement of Tmeta (° C.) will be described below.

—Average Elongation Retention Ratio—

The polymer sheet of the present invention is characterized in that the backsheet has a high adhesive force even after a lapse time under moisture and heat. To achieve the above feature, it is preferable to suppress a decrease in adhesive force by suppressing hydrolysis at the surface of the polyester film base material. From this point of view, the “average elongation retention ratio after being left to stand for 72 hours under the conditions of a temperature of 125° C. and a relative humidity of 100% RH” is adopted as a standard for the hydrolysis at the surface of a polyester film base material. In the present invention, it is necessary that the average elongation retention ratio is 10% or more.

Here, the term “elongation retention ratio (Lr)” refers to the ratio (%) of the breaking elongation (Li) before a lapse time under moisture and heat, and the breaking elongation (Lt) after a lapse time under moisture and heat and is a value determined according to the following Equation.

Lr(%)=100×(Lt)/(Li)

The “average elongation retention ratio” in the present invention is a value obtained by carrying out measurement of elongation retention ratios in the longitudinal direction (MD) of the polyester film base material and in the direction orthogonal thereto (YD), and is expressed as an average value.

Examples of a method for the adjustment of elongation retention ratio include adjustment of the “plane orientation coefficient” of the polyester film base material, adjustment of the “intrinsic viscosity” of the polyester, adjustment of the kinds and contents of the “constituent components” that constitute the polyester, addition of additives such as a “buffering agent” or a “terminal blocking agent”, adjustment of the “amount of phosphorous atoms” present in the polyester, and the like.

As the hydrolysis proceeds easier, the molecular weight gets lower, and therefore, the value of the average elongation retention ratio exhibited by the polyester film base material decreases more easily. From this point of view, it is necessary that the polyester film base material in the present invention has an average elongation retention ratio of 10% or more. The average elongation retention ratio is more preferably from 20% to 95%, and even more preferably from 30% to 90%.

By setting the average elongation retention ratio at 10% or more, peeling (adhesion failure) of the polymer sheet caused by the hydrolysis of the polyester can be effectively suppressed.

A specific method for the measurement of average elongation retention ratio is described below.

—Thermal Shrinkage Ratio and Distribution Thereof—

In one of suitable aspects of the polyester film base material according to the present invention, the thermal shrinkage ratios under the conditions of 150° C. and 30 minutes in the longitudinal direction (MD) of the polyester film base material and in the direction orthogonal thereto (TD) are each 1.0% or less, and the variation ratios of the thermal shrinkage are each from 10% to 20%.

The present inventors discovered that the adhesion failure of the backsheet due to exposure to moisture and heat over time is, in some cases, attributed to the occurrence of thermal shrinkage caused by residual strains in the polyester film. That is, when thermal shrinkage occurs due to residual strains in the polyester film exposed to moisture and heat over time, a shrinkage stress is generated by the thermal shrinkage between the sealing material such as EVA and the polyester film and this causes an adhesion failure of the backsheet.

Thermal shrinkage is reduced also in those polyester films according to the above-described JP-A No. 2010-248492 and WO 2010/110119; however, a reduction in the thermal shrinkage alone cannot sufficiently resolve the problem of adhesion failure. Meanwhile, in a suitable aspect of the polyester film according to the present invention, by distributing the thermal shrinkage, the adhesion failure-inhibiting effect can be improved.

The action thereof is not clear, but is thought to be as follows. Namely, when thermal shrinkage in the polyester film base material is uniform in a base material plane, stress also occurs uniformly, and thus the polymer layer is easily peeled off. On the contrary, as in the case of a polyester film base material according to a preferred aspect of the invention, when distribution is present in thermal shrinkage, even if sites with large thermal shrinkage are present in a base material plane, since sites with small thermal shrinkage are present in the same plane, thermal shrinkage stops at these sites (that is, shrinkage does not spread.) Thus, the shrinkage force does not reach a level that is sufficiently large to affect the entire base material, and consequently, peeling of the polymer layer is suppressed.

The variation ratio of the thermal shrinkage of the polyester film base material in a suitable aspect of the invention is preferably from 1% to 20%. The variation ratio of the thermal shrinkage is more preferably from 2% to 15%, and even more preferably from 3% to 12%.

Here, the variation ratio of the thermal shrinkage of the polyester film base material is obtained by carrying out measurement at five points at an interval of 10 cm in the longitudinal direction (MD) of the polyester film base material and in the direction orthogonal thereto (TD), respectively, and then determining the variation ratios of the thermal shrinkage (Bts) (%) from the following Equation, and selecting the larger value.

(Bts)(%)=100×(Bmax−Bmin)/(Bav)

Here, Bts represents the variation ratio of the thermal shrinkage; Bmax represents the maximum value of thermal shrinkage; Bmin represents the minimum value of thermal shrinkage; and Bav represents the average value of thermal shrinkage.

When the variation ratio of the thermal shrinkage exceeds 20%, the dimensional variation between the sites with large thermal shrinkage and the sites with small thermal shrinkage becomes too large, a crater-shaped shrinkage portion tends to occur, and concentration of stress may occur along the rim of this crater, and thus, peeling (adhesion failure) may occur easily. Whereas, when the variation ratio of the thermal shrinkage is less than 1%, the effect of suppressing shrinkage as described above is difficult to be achieved, which is not preferable.

When the area is small, such a shrinkage stress in the polyester film base material is less likely to occur. Therefore, the effect of adjusting the variation ratio of the thermal shrinkage to fall within the above range is particularly realized, when the polymer layer is pasted to a panel having a large area such as 0.5 m² or greater (more preferably 0.75 m² or greater, and even more preferably 1 m² or greater). This is because, when the area is small, the probability of coexistence of the portion with large amount of shrinkage and the portion with small amount of shrinkage is low.

Moreover, control of such thermal shrinkage ratio and variation ratio of the thermal shrinkage is particularly useful in realizing the effect on improvement of adhesion after a lapse time under moisture and heat. That is, in a case in which thermal shrinkage has occurred during wet heat aging under high humidity, and also when the humidity is high, water penetrates to the interface between the polyester film base material and an adjacent member or adjacent layer that is capable of forming a hydrogen bond with the polyester film base material, and cuts the hydrogen bond, and thus, adhesion is likely to be lowered. However, even under such circumstances, when the thermal shrinkage ratio and the variation ratio of the thermal shrinkage are controlled to fail within the above ranges, respectively, the shrinkage stress due to residual strains can be reduced, and thus, the adhesive force may be easily ensured.

The thermal shrinkage ratio of the polyester film base material according to the invention is measured under the conditions of 130° C. and 30 minutes.

A preferred range of the thermal shrinkage ratio is, both in the longitudinal direction (MD) and a direction orthogonal thereto (TD), preferably 1% or less, more preferably from −0.5% to 0.8, and even more preferably from −0.3% to 0.6% (the symbol “.” used herein means “elongation”).

When the thermal shrinkage ratio is 1% or less, the effect of adjusting a variation ratio of the thermal shrinkage to the specific range may be effectively exhibited. If the thermal shrinkage ratio exceeds 1%, the dimensional variation of the polyester film base material cannot be sufficiently suppressed, and there is a tendency that the effect of adjusting the variation ratio of the thermal shrinkage to a specific range may not be obtained. On the other hand, if elongation of the polyester film base material is achieved to an excessively large extent, there is a tendency that the effect of suppressing the dimensional variation in the polyester film base material due to the control of the variation ratio of the thermal shrinkage may not be obtained.

The thermal shrinkage ratio may be adjusted by performing a heat treatment after stretching during the formation of the polyester film base material. The temperature of the heat treatment is preferably from 150° C. to 220° C., more preferably from 160° C. to 210° C., and even more preferably from 170° C. to 200° C., and the duration is preferably from 10 seconds to 120 seconds, more preferably from 15 seconds to 90 seconds, and even more preferably from 20 seconds to 60 seconds.

Furthermore, it is preferable to allow relaxation in at least one of the vertical direction and the horizontal direction in addition to the heat treatment after stretching, and the amount of relaxation is preferably from 0.5% to 10%, more preferably from 1.5% to 9%, and even more preferably from 3% to 8%.

The variation ratio of the thermal shrinkage may be adjusted by forming a temperature distribution during the process of producing an unstretched film (raw film) by solidifying the polyester film base material on a cooling roll after the step of melt extrusion performed in the film formation. That is, when a molten body is cooled, spherulites are formed; however, if the cooling rate is varied, a distribution of these spherulites may be formed. This induces an orientation distribution during the vertical and horizontal stretching, and this is expressed as a distribution of the amount of shrinkage. The distribution of the cooling rate of such a molten body may be achieved by providing a temperature distribution to the cooling roll. Such a temperature distribution is achieved by disturbing the flow of a heat medium that is circulated in the cooling roll for temperature regulation, by providing a baffle plate. The temperature distribution is preferably from 0.2° C. to 10° C., more preferably from 0.4° C. to 5° C., and even more preferably from 0.6° C. to 3° C. This temperature distribution may be provided in any direction between the longitudinal direction and the width direction.

Along with the control of such a thermal shrinkage ratio and a variation ratio of the thermal shrinkage, as will be described below, the adhesion after a lapse of time under moisture and heat may be more effectively enhanced by incorporating a “terminal blocking agent” into the polyester, and incorporating a “trifuncttonal or higher-functional constituent component (C)” as a constituent component of the polyester.

The terminal blocking agent is capable of making the terminal group bulkier by reacting with the polyester, and this serves as an obstacle decreasing the mobility of polyester molecules. In the trifunctional or higher-functional constituent component (C), since the molecule branches via trifunctional or higher-functional group, the mobility of polyester molecules is decreased. As such, when the mobility decreases, variation of the thermal shrinkage may be easily formed. That is, stress occurs in the sites with large thermal shrinkage and the sites with small thermal shrinkage, but the polyester molecules attempt to resolve the stress (strain due to the distribution of thermal shrinkage) by moving under the effect of this stress. At this time, when the mobility decreases as described above, resolution of such a variation of thermal shrinkage is difficult to occur, and it is easier to form the variation ratio of the thermal shrinkage distribution according to the invention.

A specific method for the measurement of thermal shrinkage ratio will be described below.

—Plane Orientation Coefficient and Distribution Thereof—

The polyester film base material according to the invention preferably has a plane orientation coefficient of 0.165 or greater, more preferably from 0.168 to 0.18, and even more preferably from 0.170 to 0.175. When the plane orientation coefficient is adjusted to 0.165or greater, the molecules may be oriented, and the formation of the “semicrystalline” portion described above may be promoted, so that hydrolysis resistance may be further enhanced.

Here, the plane orientation coefficient (fₚₒ) as used herein is measured using an Abbe refractometer and is determined by the following Equation (A).

fₚₒ=(nMD+nTD)/2−nZB (A)

In the Equation (A), nMD represents the refractive index in the longitudinal direction (MD) of the film; nTD represents the refractive index in the orthogonal direction (TD) of the film; and nZD represents the refractive index in the film thickness direction. Here, the refractive index of the film in each direction may be measured based on A method defined in JIS K7142.

The plane orientation coefficient of the polyester film base material may be adjusted by increasing the stretch ratio during the film formation. Preferably, it is desirable to adjust the stretch ratio in the longitudinal direction (MD) of the film as well as the orthogonal direction (TD) of the film to 2.5 to 6.0 times. In order to adjust the plane orientation coefficient of the film to 0.165 or greater, it is preferable to adjust the stretch ratios of the MD and TD respectively to 3.0 to 5.0 times. Furthermore, the plane orientation coefficient may be enhanced by “preheating” and “multistage stretching” (will be described below) during longitudinal stretching.

Further, when the plane orientation coefficient is adjusted to 0.165 or greater, hydrolysis may be suppressed and adhesion failure due to a decrease in the molecular weight at the surface of the polyester film base material can be suppressed.

Furthermore, since film-forming stability is deteriorated when the stretch ratio is increased in order to increase the plane orientation coefficient, and further, since it is possible to suppress delamination (laminar peeling) caused by excessive progress of the plane orientation and enhance the adhesive force, the upper limit of the plane orientation coefficient of the base material is preferably 0.180 or less, and more preferably 0.175 or less.

According to the invention, it is preferable to provide a distribution to the plane orientation coefficient. The distribution of the plane orientation coefficient is preferably from 1% to 20%, more preferably from 2% to 15%, and even more preferably from 3% to 12%.

The adhesive force may be further enhanced by providing a distribution to the plane orientation coefficient. That is, since the polyester film base material shrinks after a lapse of time under moisture and heat, shrinkage stress occurs between the polyester film base material and a sealing material such as EVA, and this causes the occurrence of adhesion failure. This thermal shrinkage stress is proportional to the elastic modulus of the polyester film base material, and this is proportional to the plane orientation coefficient. Therefore, when there exists a distribution in the plane orientation coefficient of the polyester film base material, a distribution also occurs in the elastic modulus, and thereby sites with high elastic modulus (rigid) and sites with low elastic modulus (soft) are formed. The sites with low elastic modulus have a function of absorbing the thermal shrinkage stress that has occurred, and these sites serve as buffer areas and exhibit an effect of suppressing the decrease in adhesion. When the distribution of the plane orientation coefficient is less than 1%, there is a tendency that adhesion force thereof becomes weak due to that the thermal shrinkage stress may not be alleviated. On the other hand, when the distribution of the plane orientation coefficient is more than 20%, there is a tendency that adhesion failure is likely to occur since the thermal shrinkage stress may be highly concentrated to a portion where a degree of plane orientation is slight.

The distribution of the plane orientation coefficient in the polyester film base material may be formed by adjusting the preheating temperature distribution in the vertical stretching during the formation of the polyester film base material. That is, by having a preheating temperature distribution, an orientation distribution in the vertical stretching, and a crystal distribution accompanied therewith are formed, and thereby an orientation distribution in the lateral stretching is formed. The temperature distribution as used herein refers to the temperature distribution in the width direction. That is, the temperature distribution formed in the width direction causes the occurrence of a crystal distribution and an orientation distribution in the width direction after vertical stretching. These distributions form orientation unevenness across the entire surface of the film when the polyester film is stretched in the horizontal direction, and thereby a distribution in the plane orientation coefficient is formed.

The distribution of preheating temperature may be adjusted by providing a temperature distribution to the preheating roll. Specifically, it is desirable to adjust the preheating temperature distribution by disturbing the flow of a heat medium that is circulated in the preheating roil for temperature regulation, by providing a baffle plate. The temperature distribution of the preheating temperature is preferably from 0.2° C. to 10° C., more preferably from 0.4° C. to 5° C., and even more preferably from 0.6° C. to 3° C.

Along with the control of such a distribution of the plane orientation coefficient, as is described below, the adhesion after a lapse time under moisture and heat may be more effectively enhanced by incorporating a “terminal blocking agent” into the polyester, and incorporating a “functional or higher-functional constituent component” as a constituent component of the polyester.

The terminal blocking agent is capable of making the terminal bulkier by reacting with the polyester, and this serves as an obstacle decreasing the mobility of the polyester molecules. In the trifunctional or higher-functional constituent component (C), since the molecule branches via trifunctional or higher-functional group, the mobility of the polyester molecules is decreased. As such, when the mobility decreases, the plane orientation distribution may be easily formed. That is, stress difference occurs between the sites with large plane orientation and the sites with small plane orientation, but the molecules attempt to resolve the stress difference by fluidizing (creeping) under the effect of the stress difference. In this process, when the mobility of the molecules decreases as described above, resolution of such plane orientation distribution is difficult to occur, and it is easier to form the distribution of the plane orientation coefficient.

A specific method for the measurement of plane orientation coefficient is described below.

—Intrinsic Viscosity (IV)—

The polyester in the polyester film in the present invention preferably has an intrinsic viscosity (hereinafter, appropriately referred to as “IV”) in a range of from 0.6 dL/g to 1.2 dL/g. The intrinsic viscosity is more preferably from 0.65 dL/g to 1.0 dL/g, and even more preferably from 0.70 dL/g to 0.95 dL/g.

When the intrinsic viscosity of the polyester in the polyester film base material is less man 0.6 dL/g, the molecules have high mobility, and there is a tendency that the distribution of the thermal shrinkage or the plane orientation as described above is easily alleviated (resolved). When the intrinsic viscosity exceeds 1.2 dL/g, shear heat generation is likely to occur during melt extrusion, and this accelerates thermal decomposition of the polyester resin and, as a result, the amount of carboxylic acid (AV) in the polyester is likely to increase. This accelerates the hydrolysis of the polyester during wet heat aging, and there is a tendency that adhesion failure is likely to occur.

The IV of the polyester in the polyester film base material can be adjusted by adjusting the temperature and reaction time in the solid phase polymerization. In a suitable aspect of the solid phase polymerization, polyester pellets are heat treated in a nitrogen gas stream or in a vacuum, under the temperature condition of from 180° C. to 250° C., more preferably from 190° C. to 240° C., and even more preferably from 195° C. to 230° C., for a period of from 5 hours to 50 hours, more preferably from 10 hours to 40 hours, and even more preferably from 15 hours to 30 hours. The solid phase polymerization may be carried out at a constant temperature, or may be carried out while varying the temperature.

Further, with regard to the polyester raw material (pellets), which is supplied for the formation of the polyester film base material, it is preferable that the intrinsic viscosity is in a range of from 0.6 dL/g to 1.2 dL/g, in order to satisfy the hydrolysis resistance. The intrinsic viscosity is more preferably from 0.65 dL/g to 1.0 dL/g, and even more preferably from 0.70 dL/g to 0.95 dL/g. In order to enhance the hydrolysis resistance, it is preferable to increase the intrinsic viscosity. However, in a case in which the intrinsic viscosity exceeds 1.2 dL/g, it is needed to lengthen the time for solid phase polymerization during the production of the polyester resin, and the cost is remarkably increased, which is thus not preferable. Further, in a case in which the intrinsic viscosity is less than 0.6 dL/g, since the polymerization degree is low, heat resistance and hydrolysis resistance are remarkably deteriorated, which is thus not preferable. The intrinsic viscosity of the pellets can be adjusted to fall within the above preferable range, by adjusting the polymerization conditions and solid phase polymerization conditions at the time of producing the polyester resin.

A specific method for measuring the IV will be described below.

<Surface Resistance>

The polyester film according to the invention is such that the surface resistance R₀ of at least one surface is preferably from 10⁶Ω/□ to 10¹⁴Ω/□. The surface resistance R₀ is more preferably from 10⁸Ω/□ to 10¹³Ω/□, and even more preferably from 10⁹Ω/□ to 10¹²Ω/□.

A specific method for measuring the surface resistance R₀ will be described below.

When dust adheres to the surface of the polyester film, there is a case in which a gap occurs at the interface between the polyester film and the EVA (sealing agent) bonded thereon, and the adhesive force is decreased. However, when the surface resistance of the polyester film is adjusted to the range described above, the generation of static electricity may be suppressed, and the adhesion of dust to the polyester film surface caused by the generation of static electricity may be suppressed.

If the surface resistance R₀ of the polyester film surface is greater than the suitable range described above, there is a tendency that static electricity is generated, and the adhesive force is prone to decrease. On the other hand, if the surface resistance R₀ of the polyester film surface is less than the suitable range, mere is a case in which a need to contain a large amount of a conductive agent such as conductive particles or a conductive resin, occurs, and there is a tendency that the durability against heat and humidity is prone to decrease.

<Polyester>

Hereinafter, the polyester that is contained in the polyester film in the invention will be described more specifically.

The polyester that is contained in the polyester film according to the invention is a linear saturated polyester containing dicarboxylic acid constituent components and diol constituent components.

The polyester is preferably such that the proportion of an aromatic dicarboxylic acid constituent component among the dicarboxylic acid constituent components is from 90% by mole to 100% by mole. If the proportion of the aromatic dicarboxylic acid constituent component is lower than 90% by mole, there are occasions in which moisture and heat resistance, and heat resistance may decrease. When the proportion of the aromatic dicarboxylic acid constituent component among the dicarboxylic acid constituent components of the polyester in the polyester film of the invention is adjusted to the range of from 90% by mole to 100% by mole, a good balance may be achieved between the moisture and heat resistance and the heat resistance.

The proportion of the aromatic dicarboxylic acid constituent component in the polyester is more preferably from 95% by mole to 100% by mole, even more preferably from 98% by mole to 100% by mole, particularly preferably from 99% by mole to 100% by mole, and most preferably 100% by mole. That is, it is most preferable that the entirety of the dicarboxylic acid constituent component is composed of an aromatic carboxylic acid constituent component.

Suitable examples of the main repeating units consisting of the dicarboxylic acid constituent components and the diol constituent components, which mainly constitute the polyester, include ethylene terephthalate, ethylene-2,6-naphthylene dicarboxylate, propylene terephthalate, butylene terephthalate, 1,4-cyclohexylene dimethylene terephthalate, ethylene-2,6-naphthalene dicarboxylate, and mixtures thereof. The term “main repeating units” as used herein mean that the total amount of those repeating units is 70% by mole or greater of the total amount of the repeating units contained in the polyester, and the proportion is more preferably 80% by mole or greater, and even more preferably 90% by mole or greater.

Furthermore, from the viewpoints that polymerization may be carried out at low cost and more easily and the resulting polymer has excellent heat resistance, it is preferable that ethylene terephthalate, ethylene-2,6-naphthalene dicarboxylate, and a mixture thereof constitute the main constituent unit. In this case, when more of ethylene terephthalate is used as a constituent unit, a film having general-purpose usefulness and having moisture and heat resistance may be obtained at lower cost. Furthermore, when more of ethylene-2,6-naphthalene dicarboxylate is used as a constituent unit, a film having superior moisture and heat resistance may be obtained.

As copolymerization components of the polyester, various dicarboxylic acid components or ester-forming derivatives thereof and dioi components shown below may be used.

Examples of copolymerizable dicarboxylic acid components include isophthalic acid, phthalic acid, 1,4-naphthalenedicarboxylic acid, 1,5-naphthalenedicarboxylic acid, 2,6-naphthalenedicarboxylic acid, 4,4′-diphenyldicarboxylic acid, 4,4′-diphenyl ether dicarboxylic acid, and 4,4′-diphenylsulfonedicarboxylic acid. Furthermore, examples of copolymerizable alicyclic dicarboxylic acid components include 1,4-cyclohexanedicarboxylic acid.

Furthermore, examples of the diol components include aliphatic, alicyclic and aromatic diols such as ethylene glycol, 1,2-propanediol, neopentyl glycol, 1,3-butanediol, 1,4-butanediol, 1,5-pentanediol, 1,6-hexanediol, 1,2-cyclohexanedimethanol, 1,3-cyclohexanedimethanol, 1,4-cyclohexanedimethanol, diethylene glycol, triethylene glycol, polyalkylene glycol, and 2,2-bis(4′-β-hydroxyethoxyphenyl)propane.

These components may be used singly, or two or more kinds thereof may be used in combination.

The melting point of the polyester which is used with preference in the polyester film according to the invention is preferably 250° C. or higher in view of heat resistance, and is preferably 300° C. or lower in view of productivity. When the melting point is within this range, other components may be copolymerized or blended with the polyester.

Furthermore, various known additives, for example, an oxidation inhibitor, an antistatic agent, a crystallization nucleating agent, inorganic particles, and organic particles may be incorporated into the polyester. Particularly, inorganic particles or organic particles are effective for an enhancement of the handleability of the film by imparting good siipperiness to the film surface.

The polyester may be produced according to a conventionally known method for producing a polyester. That is, the polyester may be produced using a dialkyl ester as an acid component, by subjecting this component and a diol component to a transesterification reaction, and then heating the product of this reaction under reduced pressure to perform polycondensation of the product while removing excess diol component. Furthermore, the polyester may also be produced by a conventionally known direct polymerization method using a dicarboxylic acid as an acid component. Examples of a reaction catalyst that may be used include conventionally known titanium compounds, lithium compounds, calcium compounds, magnesium compounds, antimony compounds and germanium compounds.

In regard to the polyester thus obtained, the degree of polymerization may be further increased, while the terminal carboxyl group concentration may be decreased, by subjecting the polyester to solid state polymerization.

The solid state polymerization is preferably carried out in a dryer at a temperature of 200° C. to 250° C. under reduced pressure of 1 Torr or less or under a nitrogen gas stream for 5 to 50 hours.

One suitable aspect of the polyester according to the invention includes a polyester having a dicarboxylic acid constituent component, a diol constituent component, and a constituent component (p) of which the sum of the number of carboxyl groups (a) and the number of hydroxy 1 groups (b) (a+b) is 3 or greater, the polyester having a content of the constituent component (p) of from 0.005% by mole to 2.5% by mole relative to the total amount of the constituent components contained in the polyester.

—Constituent Component (p)—

The constituent component (p) of which the sum of the number of carboxyl groups (a) and the number of hydroxyl groups (b) (a+b) is 3 or greater, will be explained.

Examples of the constituent component (p) include a carboxylic acid constituent component having a number of carboxyl groups (a) of 3 or greater, a constituent component having a number of hydroxyl groups (b) of 3 or greater, and a constituent component which is an oxyacid having both hydroxyl groups and carboxyl groups in one molecule, and has a sum of the number of carboxyl groups (a) and the number of hydroxyl groups (b) (a+b) of 3 or greater.

Examples of the carboxylic acid constituent component having a number of carboxyl groups (a) of 3 or greater include, as trifunctional aromatic carboxylic acid constituent components, trimesic acid, trimellitic acid, aphthalenetricarboxylic acid, and anthracenetricarboxylic acid; as trifunctional aliphatic carboxylic acid constituent components, methanetricarboxylic acid, ethanetricarboxylic acid, propanetricarboxylic acid, and butanetricarboxylic acid; as tetrafunctional aromatic carboxylic acid constituent components, benzenetetracarboxylic acid, pyromellitic acid, benzophenonetetracarboxylic acid, naphthalenetetracarboxylic acid, anthracenetetracarboxylic acid, and perylenetetracarboxylic acid; as tetrafunctional aliphatic carboxylic acid constituent components, ethanetetracarboxylic acid, ethylenetetracarboxylic acid, butanetetracarboxylic acid, cyclopentanetetracarboxylic acid, cyclohexanetetracarboxylic acid, and adamantanetetracarboxylic acid; as pentafunctional or higher-functional aromatic carboxylic acid constituent components, benzenepentacarboxylic acid, benzenehexacarboxylic acid, naphthalenepentacarboxylic acid, naphthalenehexacarboxylic acid, naphthaleneheptacarboxylic acid, naphthaleneoctacarboxylic acid anthracenepentacarboxylic acid, anthracenehexacarboxylic acid, anthraceneheptacarboxylic acid, and anthraceneoctacarboxylic acid; as pentafunctional or higher-functional aliphatic carboxylic acid constituent components, ethanepentacarboxylic acid, ethanehexacarboxylic acid, butanepentacarboxylic acid, butaneheptacarboxylic acid, cyclopentanepentacarboxylic acid, cyclohexanepentacarboxylic acid, cyclohexanehexacarboxylic acid, adamantanepentacarboxylic acid, and adamantanehexacarboxylic acid; and ester derivatives and acid anhydrides thereof. However, the examples are not limited to these.

Furthermore, compounds obtained by adding 1-lactide, d-lactide, an oxyacid such as hydroxybenzoic acid, and a derivative thereof, or a plural number of such oxyacids connected in series, to the carboxy terminal of the carboxylic acid constituent component, are also suitably used.

Furthermore, these may be used singly, or if necessary, plural kinds may also be used.

Examples of the constituent component having a number of hydroxyl groups (b) of 3or greater that may be used with preference include, as trifunctional aromatic constituent components, trihydroxybenzene, trihydroxynaphthalene, trihydroxyanthracene, trihydroxycalchone, trihydroxyflavone, and trihydroxycoumarin; as trifunctional aliphatic alcohol constituent components, glycerin, trimethylolpropane, and propanetriol; as tetrafunctional aliphatic alcohol constituent components, compounds such as pentaerythritol; and constituent components (p) having a diol added to the hydroxy terminal of the compounds described above. These may be used singly, or if necessary, plural kinds may also be used.

Among the oxyacids having both hydroxyl groups and carboxyl groups in one molecule, examples of the constituent component of which the sum of the number of carboxyl groups (a) and the number of hydroxyl groups (b)(a+b) is 3 or greater include hydroxyisophthalic acid, hydroxyterephthalic acid, dihydroxyterephthalic acid, and dihydroxyterephthalic acid.

Furthermore, compounds obtained by adding l-lactide, d-lactide, an oxyacid such as hydroxybenzoic acid, and a derivative thereof, or a plural number of such oxyacids connected in series, to the carboxy terminal of the constituent component, are also suitably used.

Furthermore, these may be used singly, or if necessary, plural kinds may also be used.

In the case where the polyester contains a constituent component (p), the content of the constituent component (p) is preferably from 0.005% by mole to 2.5% by mole relative to the total amount of the constituent components of the polyester. The content of the constituent component (p) is more preferably from 0.020% by mole to 1% by mole, even more preferably from 0.025% by mole to 1% by mole, still more preferably from 0.035% by mole to 0.5% by mole, still more preferably from 0.05% by mole to 0.5% by mole, and particularly preferably from 0.1% by mole to 0.25% by mole.

When the content of the constituent component (p) in the polyester is 0.005% by mole or less relative to the total amount of the constituent components in the polyester, there are occasions in which the effect of enhancing moisture and heat resistance is not verified. When the content is greater than 2.5% by mole, it is difficult to realize the polyester for the reason such as gelling of the resin and difficulty in melt extrusion, and even if realization of the polymer is possible, the gel is present as a foreign substance, so that there are occasions in which biaxial stretchability is decreased when the polyester is formed into a film, or a film obtained by stretching the polyester has many foreign substance defects.

When the content of the constituent component (p) in the polyester is adjusted to the range of from 0.005% by mole to 2.5% by mole relative to the total amount of the constituent components of the polyester, moisture and heat resistance may be increased while melt extrudability is maintained. Furthermore, the stretchability at the time of biaxial stretching, or the quality of the film thus obtained may be maintained.

The constituent component (p) is preferably such that the compound that has a number of carboxyl groups (a) of 3 or greater and has carboxylic acids, is an aromatic compound, or the compound that has a number of hydroxyl groups (b) of 3 or greater and has hydroxyl groups, is an aliphatic compound. A crosslinked structure may be formed without deteriorating the orientation characteristics of the polyester film, and molecular mobility may be further decreased, while moisture and heat resistance may be further increased.

In the case where the polyester contains the constituent component (p), it is also preferable to add a buffering agent or a terminal blocking agent, which will be described below, at the time of molding.

The polyester containing the constituent component (p) is preferably a highly crystalline resin, and specifically, the polyester is preferably a polyester of which the heat of crystal melting ΔHm determined from the peak area of the melting peak in a 2^{nd} run differential scanning calorimetric chart, which is obtained according to JIS K7122 (1999) by heating the resin at a temperature increase rate of 20° C./min from 25° C. to 300° C. (1^{st} run), maintaining the resin in that state for 5 minutes, subsequently rapidly cooling the resin to a temperature of 25° C. or lower, and raising the temperature again at a temperature increase rate of 20° C./min from room temperature to 300° C., is 15 J/g or greater. Preferably, it is desirable to use a resin having a heat of crystal melting of 20 J/g or greater, more preferably 25 J/g or greater, and even more preferably 30 J/g or greater. When the polyester is made highly crystalline as such, oriented crystallization may be achieved by stretching and heat treatment, and as a result, a polyester film having excellent mechanical strength and moisture and heat resistance may be obtained.

The melting point Tm of the polyester containing the constituent component (p) is preferably 245° C. to 290° C. The melting point Tm used herein is a melting point Tm obtainable by DSC during a process of temperature increase (temperature increase rate: 20° C./min), and the temperature of a peak top that may be designated as a peak of crystal melting of a 2^{nd} run, which is obtainable by a method based on JIS K-7.121 (1999) as described above, by heating the resin at a temperature increase rate of 20° C./min from 25° C. to 300° C. (1^{st} run), maintaining the resin in that state for 5 minutes, subsequently rapidly cooling the resin to a temperature of 25° C. or lower, and raising the temperature again at a temperature increase rate of 20° C./min from room temperature to 300° C., is designated as the melting point Tm1 of the polyester. More preferably, the melting point Tm is 247° C. to 275° C., and even more preferably 250° C. to 265° C. If the melting point Tm is lower than 245° C., the film has inferior heat resistance or the like, which is not preferable. Furthermore, if the melting point Tm is higher than 290° C., it may become difficult to perform extrusion processing, and therefore, it is not preferable. When the melting point Tm of the polyester is adjusted to 245° C. to 290° C., a polyester film which achieves a good balance between heat resistance and processability may be obtained.

<Buffering Agent>

The polyester film in the invention preferably contains a buffering agent. Incorporation of a buffering agent is particularly preferable when the polyester contains the constituent component (p) as a constituent component thereof.

The buffering agent is preferably an alkali metal salt from the viewpoints of polymerization reactivity and moisture and heat resistance, and specific examples of the buffering agent include alkali metal salts with compounds such as phthalic acid, citric acid, carbonic acid, lactic acid, tartaric acid, phosphoric acid, phosphorous acid, hypophosphorous acid, and polyacrylic acid. Among these, it is preferable that the alkali metal element be potassium or sodium, from the viewpoint that precipitates based on catalyst residues are not easily produced. Specific examples of the buffering agent include potassium hydrogen phthalate, sodium dihydrogen citrate, disodium hydrogen citrate, potassium dihydrogen citrate, dipotassium hydrogen citrate, sodium carbonate, sodium tartrate, potassium tartrate, sodium lactate, potassium lactate, sodium hydrogen carbonate, disodium hydrogen phosphate, dipotassium hydrogen phosphate, potassium dihydrogen phosphate, sodium dihydrogen phosphate, sodium hydrogen phosphite, potassium hydrogen phosphite, sodium hypophosphite, potassium hypophosphite, and sodium polyacrylate.

Furthermore, the buffering agent is preferably an alkali metal salt represented by the following formula (I), from the viewpoints of the polymerization reactivity of the polyester, and heat resistance at the time of melt molding. Furthermore, an alkali metal is preferably sodium and/or potassium, from the viewpoints of polymerization reactivity, heat resistance, and moisture and heat resistance, and is particularly preferably a metal salt of phosphoric acid and sodium and/or potassium, from the viewpoints of polymerization reactivity and moisture and heat resistance.

POₓH_{y}M_{z} (I)

wherein x represents an integer from 2 to 4; y represents 1 or 2; z represents 11 or 2; and M is an alkali metal).

The content of the buffering agent is preferably from 0.1 mol/ton to 5.0 mol/ton, relative to the total mass of the polyester, and is more preferably from 0.3 mol/ton to 3.0 mol/ton. When the content of the buffering agent is in the range described above, moisture and heat resistance or mechanical characteristics may be further enhanced.

In the case of using an alkali metal salt represented by the formula (I) as the buffering agent, it is preferable to use phosphoric acid together. Thereby, the effect of suppressing hydrolysis by the buffering agent may be further increased, and the moisture and heat resistance of the polyester fun thus obtainable may be further increased.

In that case, it is preferable to adjust the alkali metal element content W1 in the polyester film to the range of from 2.5 ppra to 125 ppm, and to adjust the ratio of the alkali metal element content W1 and the phosphorus element content W2, W1/W2, to the range of from 0.01 to 1. When the contents are adjusted to these ranges, the effect of suppressing hydrolysis may be further enhanced. More preferably, the alkali metal element W1 is from 15 ppm to 75 ppm, and the ratio of the alkali metal element content W1 and the phosphorus element content W2, W1/W2, is from 0.1 to 0.5. If the alkali metal element content W1 is less than 2.5 ppm, the effect of suppressing hydrolysis is insufficient, and the resulting polyester film may not obtain sufficient moisture and heat resistance. Furthermore, if the alkali metal element content is greater than 125 ppm, the alkali metal which is present in excess may accelerate a thermal decomposition reaction at the time of melt extrusion, and the molecular weight may decrease, thereby causing a decrease in moisture and heat resistance or in the mechanical properties. Furthermore, when the ratio of the alkali metal element content W1 and the phosphorus element content W2, W1/W2, is less than 0.1, the effect of suppressing hydrolysis is insufficient. When the ratio is greater than 125 ppm, the excess phosphoric acid reacts with the polyester during the polymerization reaction to form a phosphoric acid ester skeleton into a molecular chain, and this part accelerates the hydrolysis reaction, so that hydrolysis resistance may decrease.

When the alkali metal element W1 in the polyester film is from 15 ppm to 75 ppm, and the ratio of the alkali metal element contents W1 and W2, W1/W2, is from 0.1 to 0.5, the effect of suppressing hydrolysis resistance may be further increased, and as a result, high moisture and heat resistance may be obtained.

The buffering agent may be added during the polymerization of polyester, or may be added at the time of melt molding, but from the viewpoint of uniform dispersion of the buffering agent in the film, it is preferable to add the buffering agent during the polymerization. When the buffering agent is added during the polymerization, the timing of addition is such that the buffering agent may be added at any time between the completion of the esterification reaction or transesterification reaction during the polymerization of the polyester, and the early stage of the polycondensation reaction (when the intrinsic viscosity is less than 0.3). The method for addition of the buffering agent may be any of a method of directly adding a powder, and a method of preparing a solution in which die buffering agent is dissolved in a diol constituent component such as ethylene glycol and adding the solution; however, it is preferable to add the buffering agent as a solution in which the buffering agent is dissolved in a diol constituent component such as ethylene glycol. In that case, in regard to the solution concentration, if the solution is diluted to 10% by mass or less and added, it is preferable from the viewpoints that there occurs less adhesion of the buffering agent to the vicinity of the addition port, the error in the amount of addition is small, and the reactivity is satisfactory.

Furthermore, in the case of a polyester containing the constituent component (p), it is preferable that the content of diethylene glycol, which is a side product produced during the polymerization, be less than 2.0% by mass, and more preferably less than 1.0% by mass, from the viewpoints of heat resistance and moisture and heat resistance.

<Terminal Blocking Agent>

According to one preferred aspect, the polyester film in the invention contains a terminal blocking agent. The terminal blocking agent is an additive that reacts with the terminal carboxyl group of the polyester and thereby reducing the amount of carboxyl terminals of the polyester.

Examples of the terminal blocking agent include carbodiimide compounds, epoxy compounds, and oxazoline compounds.

The terminal blocking agent is more effective when added together with the polyester during the formation of a polyester film. It is also acceptable to use the terminal blocking agent at the time of solid state polymerization.

The terminal blocking agent may also be used together with the polyester containing the constituent component (p) of which the sum of the number of carboxyl groups (a) and the number of hydroxyl groups (b) (a+b) is 3 or greater.

The content of the terminal blocking agent in the polyester film is preferably 0.1% by mass to 5% by mass. If the content of the terminal blocking agent is less than 0.1% by mass, the effect of blocking the carboxyl group is small, and the hydrolysis resistance may be deteriorated. Furthermore, if the content of the terminal blocking agent is larger than 5% by mass, foreign materials may be produced to a large extent during film formation, a decomposition gas may be generated, or the productivity may be affected. A more preferred upper limit of the content of the terminal blocking agent is 4% by mass, and an even more preferred upper limit thereof is 2% by mass. A more preferred lower limit of the content of the terminal blocking agent is 0.3% by mass, and an even more preferred lower limit thereof is 0.5% by mass. A more preferred range of the content of the terminal blocking agent is 0.3% by mass to 4% by mass, and an even more preferred range is 0.5% by mass to 2% by mass.

—Carbodiimide Compound—

The carbodiimide compounds are classified into monofunctional carbodiimides and polyfunctional carbodiimides.

Examples of the monofunctional carbodiimides include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, and di-β-naphthylcarbodiimide. Particularly preferred examples include dicyclohexylcarbodiimide and diisopropylcarbodiimide.

Furthermore, carbodiimides having a degree of polymerization of 3 to 15 are preferably used as the poly functional carbodiimides. The polyfunctional carbodiimide generally includes a repeating unit represented by the following formula —R—N═C═N— and the like. Here, R represents a divalent linking group such as alkylene group, arylene group and the like. As the repeating unit, specific examples include 1,5-naphthalenecarbodiimide, 4,4′-diphenylmethanecarbodiimide, 4,4′-diphenyldimethymethanecarbodiimide, 1,3-phenylenecarbodiimide, 1,4-phenylene carbodiimide, 2,4-tolylenecarbodiimide, 2,6-tolylenecarbodiimide, a mixture of 2,4-tolylenecarbodiimide and 2,6-tolylenecarbodiimide, hexamethylenecarbodiimide, cyclohexane-1,4-carbodiimide, xylylenecarbodiimide, isophoronecarbodiimide, isophoronecarbodiimide, dicyclohexylmethane-4,4′-carbodiimide, methylcyclohexanecarbodiimide, tetramethylxylylenecarbodiimide, 2,6-diisopropylphenylcarbodiimide, and 1,3,5-triisopropylbenzene-2,4-carbodiimide.

These may be used singly or in combination of two or more kinds thereof.

Since the carbodiimide compounds generate isocyanate-based gases as a result of thermal decomposition, carbodiimide compounds having high heat resistance are preferred. In order to increase heat resistance, carbodiimide compounds having a higher molecular weight (degree of polymerization) are preferred, and it is more preferable to impart a structure having high heat resistance to the terminals of the carbodiimide compound. Furthermore, if a carbodiimide compound once undergoes thermal decomposition, the carbodiimide compound is prone to undergo another thermal decomposition. Therefore, it is needed to devise a process in a way such as lowering the extrusion temperature of the polyester as much as possible.

—Epoxy Compounds—

Preferred examples of the epoxy compounds include glycidyl ester compounds and glycidyl ether compounds.

Specific, examples of the glycidyl ester compounds include benzoic acid glycidyl ester, t-butylbenzoic acid glycidyl ester, p-toluic acid glycidyl ester, cyclohexanecarboxylic acid glycidyl ester, pelargonic acid glycidyl ester, stearic acid glycidyl ester, lauric acid glycidyl ester, palmitic acid glycidyl ester, behenic acid glycidyl ester, versatic acid glycidyl ester, oleic acid glycidyl ester, linolic acid glycidyl ester, linoleic acid glycidyl ester, behenolic acid glycidyl ester, stearolic acid glycidyl ester, terephthalic acid diglycidyl ester, isophthalic acid diglycidyl ester, phthalic acid diglycidyl ester, naphthalenedicarboxylic acid diglycidyl ester, methylterephthalic acid diglycidyl ester, hexahydrophthalic acid diglycidyl ester, tetrahydrophthalic acid diglycidyl ester, cyclohexanedicarboxylic acid diglycidyl ester, adipic acid diglycidyl ester, succinic acid diglycidyl ester, sebacic acid diglycidyl ester, dodecanedioic acid diglycidyl ester, octadecanedicarboxylic acid diglycidyl ester, trimellitic acid triglycidyl ester, and pyromellitic acid tetraglycidyl ester. These may be used singly or in combination of two or more kinds thereof.

Specific examples of the glycidyl ether compounds include phenyl glycidyl ether, O-phenyl glycidyl ether, 1,4-bis(β,γ-epoxypropoxy)butane, 1,6-bis(β,γ-epoxypropoxy)hexane, 1,4-bis(β,γ-epoxypropoxy)benzene, 1-(β,γ-epoxypropoxy)-2-ethoxyethane, 1-(β,γ-epoxypropoxy)-2-benzyloxyethane, 2,2-bis[p-(β,γ-epoxypropoxy)phenyl]propane, 2,2-bis(4-hydroxyphenyl)propane, and a bisglycidyl polyether which is obtainable by a reaction between bisphenol such as 2,2-bis(4-hydroxyphenyl)methane and epichlorohydrin. These may be used singly or in combination of two or more kinds thereof.

—Oxazoline Compounds—

The oxazoline compounds are preferably bisoxazoline compounds, and specific examples include 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline) 2,2′-bis(4-cyclohexyl-2-oxazoline), 2,2′-bis(4-benzyl-2-oxazoline), 2,2′-p-phenylenebis(2-oxazoline), 2,2′-m-phenylenebis(2-oxazoline), 2,2′-o-phenylenebis(2-oxazoline), 2,2′-p-phenylenebis(4-methyl-2-oxazoline), 2,2′-p-phenylenebis(4,4-dimethyl-2-oxazoline) 2,2′-m-phenylenebis(4-methyl-2-oxazoline), 2,2′-m-phenylenebis(4,4-dimethyl-2-oxazoline), 2,2′-ethylenebis(2-oxazoline), 2,2′-tetramethylenebis(2-oxazoline), 2,2′-hexamethylenebis(2-oxazoline), 2,2′-octamethylenebis(2-oxazoline), 2,2′-decamethylenebis(2-oxazoline), 2,2′-ethylenebis(4-methyl-2-oxazoline), 2,2′-tetramethylenebis(4,4-dimethyl-2-oxazoline), 2,2′-9,9′-diphenoxyethanebis(2-oxazoline), 2,2′-cyclohexylenebis(2-oxazoline) and 2,2′-diphenylenebis(2-oxazoline). Among these, 2,2′-bis(2-oxazoline) is most preferably used from the viewpoint of the reactivity with the polyester.

The bisoxazoline compounds may be used singly or in a combination two or more kinds thereof.

<Phosphorus Compound>

For the polyester film in the invention, it is also preferable to incorporate a phosphorus compound from the viewpoint of suppressing the decomposition of hydrolysis.

In the case of incorporating a phosphorus compound, it is preferable that the amount of phosphorus atoms determined by a fluorescent X-ray analysis of the polyester film be 200 ppm or greater and 3000 ppm or less. The amount of phosphorus atoms is more preferably 300 ppm or greater and 2000 ppm or less, and even more preferably 400 ppm or greater and 1500 ppm or less.

As the phosphorus compound, it is preferable to use one or more phosphorus compounds selected from the group consisting of phosphoric acid, phosphorous acid, phosphonic acid, and methyl esters, ethyl esters, phenyl esters, and half esters of those acids, and other derivatives thereof. According to the invention, methyl esters, ethyl ester and phenyl esters of phosphoric acid, phosphorous acid and phosphonic acid are particularly preferred. Furthermore, as a method of incorporating the phosphorus compound, it is preferable to add the phosphorus compound when polyester raw material chips are produced.

<Other Additives>

Since the polyester film in the invention is a constituent element of a backsheet for a solar cell (in some cases, it may be also referred to a solar cell backsheet), it is preferable that the polyester film is not easily affected by deterioration due to sunlight. For that reason, a UV (ultraviolet) absorber or a substance having a characteristic of reflecting UV may be added into the polyester. Furthermore, according to one preferred aspect, the average reflective ratio for a radiation having a wavelength of 400 nm to 700 nm at at least one surface of the film is adjusted to 80% or greater. The average reflective ratio is more preferably 85% or greater, and particularly preferably 90% or greater. When the average reflective ratio of a radiation having a wavelength of 400 nm to 700 nm is adjusted to 80% or greater, even if a solar cell using the film of the invention is used at places which are directly exposed to sunlight, deterioration of the film occurs to a lesser extent.

(Method for Producing Polyester Film)

Next, the method for producing the polyester film in the invention will be explained by way of an example of a biaxially oriented polyester film which uses polyethylene terephthalate (PET) as the polyester, as a representative example.

Of course, the invention is not intended to be limited to the biaxially oriented polyester film which uses a PET film, and films which use any other polymers axe also acceptable. For example, when a polyester film is constructed using polyethylene-2,6-naphthalenedicarboxylate, which has a high glass transition temperature or a high melting point, extrusion or stretching may be carried out at higher temperatures than the temperatures shown below.

<Film Formation/Extrusion>

The polyester film in the invention is produced, for example, as follows.

First, a raw (unstretched) polyester sheet that constitutes the polyester film is produced. In order to produce a raw polyester sheet, for example, pellets of the polyester prepared as described above are melted using an extruder, and the molten product is ejected through a nozzle (die) and then is molded into a sheet form through cooling and solidification. At this time, it is preferable to filter the polymer through a fiber-sintered stainless steel metal filter so as to remove unmelted matter in the polymer.

Furthermore, it is also another preferred aspect to add inorganic particles or organic particles, for example, inorganic particles of clay, mica, titanium oxide, calcium carbonate, kaolin, talc, wet silica, dry silica, colloidal silica, calcium phosphate, barium sulfate, alumina, zirconia and the like; organic particles constituted of acrylic resins, styrene-based resins, thermosetting resins, silicones, imide-based compounds and the like; and particles that are precipitated due to the catalyst and the like added during the polymerization reaction of the polyester (so-called internal particles), in order to impart good slipperiness, abrasion resistance, scratch resistance and the like to the surface of the polyester film.

Furthermore, as long as the effects of the invention are not impaired, various additives, for example, a compatibilizing agent, a plasticizer, a weather resistant agent, an oxidation inhibitor, a thermal stabilizer, a gliding agent, an antistatic agent, a brightening agent, a colorant, an electroconductive agent, an ultraviolet absorber, a flame retardant, a flame retardant aid, a pigment and a dye, may also be added.

When such an additive or a terminal blocking agent is incorporated into the polyester, a method of mixing the terminal blocking agent directly with PET pellets, kneading the mixture using a vent type twin-screw kneading extruder which has been heated to a temperature of 270° C. to 275° C., and forming the kneading product into a high concentration master pellet, is effective.

Subsequently, the pellets of PET thus obtained are dried under reduced pressure for 3or more hours at a temperature of 180° C., and then the dried pellets are supplied to an extruder which has been heated to a temperature of 265° C. to 280° C., more preferably to a temperature of 270° C. to 275° C., under a nitrogen gas stream or under reduced pressure so as to prevent the intrinsic viscosity from decreasing. The pellets are extruded through a slit die and cooled on a casting roll, and thus an unstretched film is obtained. In this case, it is preferable to use various filters, for example, filters made of materials such as sintered metals, porous ceramics, sand and iron wire, in order to remove foreign materials or degenerate polymer. Furthermore, a gear pump may also be provided if necessary, in order to improve metered supply. In the case of laminating a film, plural different polymers are melt laminated using two or more extruders and a manifold or a joint block. Melt lamination is used preferably when, for example, the reflective layer (white layer) is co-extruded.

The molten body (melt) extruded from an extruder as such is solidified on a casting (cooling) roll to which a temperature distribution has been imparted as described above, and thus a raw film (unstretched film) is obtained. A preferred temperature of the cooling roll is preferably from 10° C. to 60° C., more preferably from 15° C. to 55° C., and even more preferably from 20° C. to 50° C. At this time, in order to enhance the adhesive force between the melt and the cooling roll, an electrostatic application method, an air knife method, a method of forming a water film on the cooling roll, and the like may be preferably used.

Furthermore, according to the invention, when the melt is extruded onto a cast roll, it is preferable to set the linear velocity of the cast roll to 10 m/min or greater, more preferably from 15 m/min to 50 m/min, and even more preferably from 18 m/min to 40 m/min. If the linear velocity is equal to or less than this range, the retention time of the melt on the cast roll is lengthened, and especially, the temperature difference given by this method becomes even, so that the effects are reduced. On the other hand, if the linear velocity is greater than this range, thickness irregularity of the melt is prone to occur, and the temperature unevenness of the melt caused by the thickness irregularity exceeds the range described above, which is not preferable. In order to achieve such a velocity of the east roll, it is necessary to set the kneading speed in the extruder to a high level, and in conventional methods, the AV is prone to increase due to the shear heat generation of the resin along with an increase in the speed of rotation of the screw. Such a phenomenon is prone to be manifested particularly conspicuously in the present invention which uses a resin having a high IV. For this reason, the invention is characterized by adding fine particles of a resin to the extruder. That is, the time point at which shear heat generation is most likely to occur is the initiation of melting during the early stage of kneading, and in this stage, pellets and the screw strongly rub against each other and generate heat. By adding fine particles of a resin at this stage, the friction between the pellets is reduced, and an increase in the AV is suppressed, so that the AV may be adjusted to the range of the invention. The size of these fine particles is preferably set to the range of from 200 meshes to 10 meshes, and the fine particles are obtained by crushing the pellets and sieving the crushed product. The amount of addition of these fine particles is preferably from 0.1% to 5%, more preferably from 0.3% to 4%, and even more preferably from 0.5% to 3%. When the amount of addition is less than this range, the effects described above are insufficient, and when the amount of addition is greater than this range, abrasion with the screw becomes too strong, and slippage occurs. Furthermore, thickness unevenness of the melt occurs due to a fluctuation in ejection, and the temperature distribution on the cast roll exceeds the range of the invention, which is not preferable.

<Film Formation/Longitudinal Stretching>

Subsequently, the raw film (unstretched film) is obtained above, is biaxially stretched in the longitudinal direction and the lateral direction and then heat treated. The method of performing biaxial stretching includes a sequential biaxial stretching method of performing stretching in the longitudinal direction and the width direction separately, as described above, a simultaneous biaxial stretching method of performing stretching in the longitudinal direction and the width direction at the same time, and further a combination method of the sequential biaxial stretching method and the simultaneous biaxial stretching method, and the like.

Here, the biaxially stretching, in which an unstretched film is stretched in the longitudinal direction by a longitudinal stretching machine with several rolls by using the difference of circumferential velocity of rolls (MD stretching) and then stretched in the lateral direction by a tentor (TD stretching), is described.

In the invention, while the unstretched film is firstly stretched with MB stretching, it is preferable to preheat sufficiently the unstretched film before MD stretching. A temperature of the preliminary heating is preferably from 40° C. to 90° C., more preferably from 50° C. to 85° C. and even more preferably from 60° C. to 80° C. The preheat is conducted by passing the raw film on a heat (temperature control) roll to which a temperature distribution in the lateral direction has been imparted as described above. A time of the preliminary heating is preferably from 1 second to 120 seconds, more preferably from 5 seconds to 60 seconds, and even more preferably 10 seconds to 40 seconds. MD stretching can be carried out by a single stage or a multistage.

In the single stage, the temperature of the MD stretching is from a glass-transition temperature (Tg) to Tg+15° C. (more preferably to Tg+10° C.). The stretch ratio is preferably set to from 2.0 times to 6.0 times, more preferably from 3.0 times to 5.5 times, and even more preferably from 3.5 times to 5.0 times. It is preferable to be cooled with a group of rolls at a temperature of from 20° C. to 50° C. after stretching.

Since a polyester in the polyester film in the invention has a larger IV and a higher molecular weight, a molecular mobility thereof is decreased, and oriented crystallization may hardly occur. Therefore, it is preferable to carry out the multistage stretching. First, stretching is carried out in a low temperature and thereafter a second stretching is carried out in a higher temperature, and thereby the oriented crystallization is achieved to obtain a high orientation. The first low temperature stretching (MD1 stretching) is carried out by heated with a group of heating rolls in a range from (Tg−20° C.) to (Tg+10° C.), and more preferably from (Tg−10° C.) to (Tg+5° C.). The polyester film is stretched at a stretching ratio of preferably from 1.1 times to 3.0 times in the longitudinal direction, more preferably from 1.2 times to 2.5 times, and even more preferably from 1.5 times to 2.0 times, and then MD2 stretching is carried out in a range from (Tg+10° C.) to (Tg+50°G) which is higher than MD1 stretching temperature. Preferable temperature at MD2 stretching is from (Tg+15° C.) to (Tg+30° C.) and MD2 stretching ratio is preferably from 1.2 times to 4.0 times, and more preferably from 1.5 times to 3.0 times. A total MD stretching ratio combined MD1 stretching and MD2 stretching is preferably from 2.0 times to 6.0 times, more preferably from 3.0 times to 5.5 times, and even more preferably from 3.5 times to 5.0 times. The ratio of stretching ratio of the first stage and the second stage (refereed to a multistage ratio=the second stage/the first stage) is preferably from 1.1 times to 3 times, more preferably from 1.15 times to 2 times, and even more preferably from 1.2 times to 1.8 times.

It is preferable to be cooled with a group of rolls at a temperature of from 20° C. to 50° C. after stretching.

<Film Formation/Lateral Stretching>

Subsequently, the film is stretched in the width direction by using a tenter (also referred to as a stentor) at a stretch ratio of from 2.0 times to 6.0 times, preferably from 3.0 times to 5.5 times, and more preferably from 3.5 times to 5.0 times. A range of temperature of stretching is (Tg) to (Tg+50° C.) and preferably from (Tg) to (Tg+30° C. (TD stretching). Here, Tg represents a glass transition temperature of a material (polyester). Tg may be measured based on JIS K7121, ASTM D3418-82 or the like. In the invention, for example, Tg is measured with differential scanning calorimeter (DSC) manufactured by SHIMADZU CO. LTD.

<Heat Treatment>

After the stretching, the thus stretched film is subjected to a heat treatment. The heat treatment can be subjected to by a conventionally known arbitrary method using a tenter, a heating oven, a heated roll or the like. This heat treatment is generally subjected to at a temperature of not higher than the melting point of the polyester; however, in the present invention, it is preferred that the heat treatment be subjected to at the above-described temperature for the above-described time. In this case, in order to achieve the thermal shrinkage of the present invention, it is preferred that the film be relaxed at least in either of the longitudinal and transverse directions in the above-described manner.

The film heat-treated in this manner is then wound to obtain the polyester film according to the present invention.

<Surface Treatment>

It is preferred that at least one surface of the polyester film be subjected to a surface treatment. The surface treatment is preferably at least one selected from a flame treatment in which a silane compound is introduced into a flame (hereinafter, referred to as “ITRO treatment” as appropriate) and an atmospheric-pressure plasma treatment (hereinafter, referred to as “APP treatment” as appropriate). It is preferred that the surface treatments) be performed on at least a surface onto which a coating liquid for forming the below-described specific polymer layer is applied.

These surface treatments will now be described.

(1) Flame Treatment Using a Flame Introduced with a Silane Compound (ITRO Treatment)

Examples of flame treatment using a flame introduced with a silane compound include silicate flame treatments and, thereamong, an ITRO treatment is preferred. The above-described “ITRO treatment” refers to a surface treatment method in which a nano-level silicon oxide film is formed on a subject to be coated by using an oxidizing flame of a flame burner. That is, the above-described ITRO treatment is different from conventional pretreatments in which only the surface of a base material is modified (e.g., flame treatment, corona treatment plasma treatment) and refers to a surface treatment in which a readily-adhesive substance is actively added to a surface.

The type of the silane compound is not particularly limited, and examples thereof include alkylsilane compounds and alkoxysilane compounds.

Further, preferred examples of the alkylsilane compounds and alkoxysilane compounds include tetramethylsilane, tetraethylsilane, dimethyldichlorosilane, dimethyldiphenylsilane, diethyldichlorosilane, diethyldiphenylsilane, methyltrichlorosilane, methyltriphenylsilane, dimethyldiethylsilane, tetramethoxysilane, tetraethoxysilane, methyltrimethoxysilane, dimethyldimethoxysilane, phenyltrimethoxysilane, dichlorodimethoxysilane, dichlorodiethoxysilane, diphenyldimethoxysilane, diphenyldiethoxysilane, trichloromethoxysilane, trichloroethoxysilane, triphenylmethoxysilane, triphenylethoxysilane and combinations of two or more of these compounds.

Further, it is more preferred that the silane compound be one which contains at least one of a nitrogen atom, a halogen atom, a vinyl group and an amino group in the molecule or at a molecular end.

More specifically, it is preferred that, the silane compound be at least one of hexamethyldisilazane (boiling point: 126° C.), vinyltrimethoxysilane (boiling point: 123° C.), vinyltriethoxysilane (boiling point: 161° C.), trifluoropropyltrimethoxysilane (boiling point: 144° C.), trifluoropropyltrichlorosilane (boiling point: 113 to 114° C.), 3-aminopropyl trimethoxysilane (boiling point: 215° C.), 3-aminopropyl triethoxysilane (boiling point: 217° C.), hexamethyldisiloxane (boiling point: 100 to 101° C.) and 3-chloropropyl trimethoxysilane (boiling point: 196° C.). By using such a silane compound, not only the compatibility with a carrier gas is improved and the polyester film is more uniformly modified with formation of a particulate matter (silica layer) on the surface of a carbon compound, but also the silane compound becomes more likely to partially remain on the surface of the carbon compound due to the relation of the boiling point and the like and a superior adhesive force can thus be attained between the polyester film and a coating layer containing a fluorine-based polymer.

Further, it is preferred that the average molecular weight of the silane compound, which is determined by mass spectrometry, be in the range of 50 to 1,000. The average molecular weight of the silane compound, which is determined by mass spectrometry, is more preferably in the range of 60 to 500, still more preferably in the range of 70 to 200.

It is preferred that the flame temperature be set in the range of 400 to 2,500° C. The flame temperature is set more preferably in the range of 500 to 1,800° C., still more preferably in the range of 800 to 1,200° C.

It is also preferred that an ITRO treatment apparatus be equipped with a burner for generating a flame. The type of such burner is not particularly limited, and it may be any of, for example, a premix-type burner, a diffusion-type burner, a partial premixing-type burner, an atomization burner, an evaporation burner and a pulverized coal burner.

Further, it is preferred that the ITRO treatment apparatus be also equipped with another heat source in addition to the burner. The type of such heat source is not particularly limited, and it is preferably at least one heating means selected from the group consisting of a laser, a halogen lamp, an infrared lamp, a high-frequency coil, an induction heating apparatus, a hot-air heater and a ceramic heater.

For example, by using a laser, the surface treatment of the carbon compound can be performed by extremely rapidly heating the carbon compound in spots and thermally decomposing the silane compound.

Further, by using a halogen lamp or an infrared lamp, a large amount of the silane compound can be thermally decomposed with an extremely uniform temperature distribution, so that the surface treatment of the carbon compound can be performed efficiently.

Moreover, by using a high-frequency coil or an induction heating apparatus, the carbon compound can be extremely rapidly heated to thermally decompose the silane compound, so that the surface treatment of the carbon compound can be performed efficiently.

Furthermore, by using a hot-air heater or a ceramic heater, for example, a treatment at a temperature of higher man 2,000° C. can be performed in a variety of sizes ranging from a small scale to a large scale, so that the silane compound can be easily thermally decomposed and the surface treatment of the carbon compound can thus be performed efficiently.

As for other preferred aspects of the flame treatment using a flame introduced with a silane compound, for example, those methods described in WO 2003/069017, WO 2004/014989, JP-A No. 2003-238710, JP-A No. 2007-039508 and JP-A No. 2008-050629 can be employed.

(2) Atmospheric-Pressure Plasma Treatment (APP Treatment)

An atmospheric-pressure plasma treatment is a method in which a stable plasma discharge is generated at an atmospheric pressure using a high-frequency wave.

In the atmospheric-pressure plasma treatment, as a carrier gas, for example, an argon gas or a helium gas partially mixed with an oxygen gas or the like is preferably used and a mixture of air and an argon gas is more preferably used.

The atmospheric-pressure plasma treatment is performed preferably at an atmospheric pressure or a near-atmospheric pressure of about 500 to 800 Torr, more preferably at 700 to 800 Torr.

Further, the power source frequency of the discharge is preferably 1 to 100 kHz, more preferably about 1 to 10 kHz. When the power source frequency is 1 kHz or higher, a stable discharge is generated, which is preferred. On another front, when the power source frequency is 100 kHz or lower, an expensive apparatus is not required, which is preferred from the standpoint of the cost of the production method.

The discharge intensity in the atmospheric-pressure plasma treatment is not particularly limited; however, in the present invention, it is preferably about 50 W·min/m² to 500 W·min/m². When the discharge intensity of the atmospheric-pressure plasma treatment is 500 W·min/m² or less, since an arc discharge is not likely to occur, the atmospheric-pressure plasma treatment can be performed stably. Meanwhile, when the discharge intensity is 50 W·min/m² or higher, sufficient surface treatment effect can be attained.

The treatment time is preferably 0.05 to 100 seconds, more preferably about 0.5 to 30 seconds. When the treatment time is 0.05 second or longer, sufficient adhesion-improving effect is attained, while when the treatment time is 100 seconds or shorter, problems of deformation, coloration and the like of a support are less likely to occur.

In the atmospheric-pressure plasma treatment a plasma generation method is not particularly limited and, in the present invention, a plasma can be generated by using, for example, a direct-current glow discharge apparatus, a high-frequency discharge apparatus or a microwave discharge apparatus. Particularly, a method in which a discharge apparatus using a high-frequency wave of 3.56 MHz is employed is preferred.

As for other preferred aspects of the atmospheric-pressure plasma treatment, for example, those methods described in Japanese Patent No. 3835261 and the like can be employed.

(Polymer Layer)

In the solar cell backsheet according to the present invention, at least one polymer layer is arranged on the above-described polyester film base material and the above-described at least one polymer layer contains at least a fluorine-based polymer, has a crosslinked structure derived from at least one crosslinking agent selected from carbodiimide-based compounds and oxazoline-based compounds and is formed by coating (hereinafter, referred to as “specific polymer layer” as appropriate).

<Specific Polymer Layer>

The specific polymer layer is a polymer layer which contains at least a fluorine-based polymer and has a crosslinked structure derived from at least one crosslinking agent selected from carbodiimide-based compounds and oxazoline-based compounds.

The solar cell backsheet may contain only one specific polymer layer, or may contain two or more specific polymer layers. When the solar cell backsheet contains two or more specific polymer layers, these two or more specific polymer layers may each have a different function from one another, or may have the same function.

In the present invention, it is preferred that the specific polymer layer be formed directly onto the polyester film since the constitution of containing a fluorine-based polymer and a crosslinked structure derived from a specific crosslinking agent improves the adhesion with the polyester film, which is the base material, as well as the adhesion between layers (particularly, the adhesion between the specific polymer layer and the sealing material provided on the cell-side substrate). Further, it is also preferred to use the specific polymer layer as the outermost layer exposed to the external environment, namely a back layer, since a polymer layer having moist heat-resistant storage stability is formed.

Depending on the case, this polymer layer can be constituted with other components), and the constituent component varies depending on the application of the polymer layer. The polymer layer may be constituted as, for example, a colored layer which imparts a sunlight-reflecting function, external design property and the like, a back layer arranged on the opposite side of the sunlight incident side, or a readily-adhesive layer which adheres the backsheet with the sealing material sealing the photovoltaic element on the cell-side substrate.

In a case in which the polymer layer is constructed as, for example, a reflective layer that reflects sunlight to the incident side thereof, the polymer layer may further contain a colorant such as a white pigment. In this case, the reflective layer is formed as a polymer layer including a fluorocarbon-based polymer. In the case of disposing two or more polymer layers on a polyester film base material, a laminate structure of: white layer (polymer layer)/polymer layer/polyester film base material may be used. The white layer may be constructed as a reflective layer. It is possible to further enhance the adhesiveness and adhesion of the reflective layer in the polymer sheet.

—Fluorine-Based Polymer—

The fluorine-based polymer contained in the specific polymer layer is not particularly limited as long as it is a polymer having a repeating unit represented by the formula, —(CFX¹—CX²X³)— (wherein X¹, X² and X³ each independently represent a hydrogen atom, a fluorine atom, a chlorine atom or a perfluoroalkyl group having 1 to 3 carbon atoms).

Examples of such fluorine-based polymer include polytetrafluoroethylene (hereinafter, may be referred to as “PTFE”), polyvinyl fluoride (hereinafter, may be referred to as “PVF”), polyvinylidene fluoride (hereinafter, may be referred to as “PVDF”), polychlorotrifluoroethylene (hereinafter, may be referred to as “PCTFE”) and polytetrafluoropropylene (hereinafter, may be referred to as “HFP”).

Thereamong, it is preferred to use PTFE or PCTFE.

These polymers may be homopolymers obtained by polymerization of single monomer or copolymers of two or more kinds of monomers. Examples thereof include a copolymer obtained by copolymerization of tetrafluoroethylene and tetrafluoropropylene (hereinafter, abbreviated as “P(TFE/HFP)”) and a copolymer obtained by copolymerization of tetrafluoroethylene and vinylidene fluoride (hereinafter, abbreviated as “P(TFE/VDF)”).

Further, the polymer used in the fluorine-based polymer-containing specific polymer layer may also be a polymer obtained by copolymerization of a fluorine-based monomer represented by the formula, —(CFX¹—CX²X³)—, and other monomer. Examples of such a polymer include a copolymer of tetrafluoroethylene and ethylene (hereinafter, abbreviated as “P(TFE/E)”); a copolymer of tetrafluoroethylene and propylene (hereinafter, abbreviated as “P(TFE/P)”); a copolymer of tetrafluoroethylene and vinyl ether (hereinafter, abbreviated as “P(TFE/VE)”); a copolymer of tetrafluoroethylene and perfluorovinyl ether (hereinafter, abbreviated as “P(TFE/FVE)”); a copolymer of chlorotrifluoroethylene and vinyl ether (hereinafter, abbreviated as “P(CTFE/VE)”); and a copolymer of chlorotrifluoroethylene and perfluorovinyl ether (hereinafter, abbreviated as “P(CTFE/FVE)”).

Among these homopolymers and copolymers, it is preferred to use P(TFE/E) or P(CTFE/VE).

These fluorine-based polymers may be polymers that are used in the form of a solution of a polymer in an organic solvent, or may be polymers that are used in the form of a dispersion of polymer particles in water. Because of environmental burden, a dispersion of polymer particles in water is preferred. Examples of aqueous dispersions of fluorine-based polymers include those described in JP-A No. 2003-231722, JP-A No. 2002-20409, and JP-A No. 9-194538. As the fluorine-based polymer, a commercial product such as OBBLIGATO SW0011F (trade name, manufactured by AGC Coat-Tech Co., Ltd.; fluorine-based binder), ZEFFLE (trade name, manufactured by DAIKIN INDUSTRIES Ltd.) and the like may be preferably used in the invention.

As the binder of the specific polymer layer containing the fluorine-based polymer in the invention, the fluorine-based polymers may be used singly, or two or more kinds thereof may be used in a combination. Furthermore, a resin other than a fluorine-based polymer, such as an acrylic resin, a polyester resin, a polyurethane resin, a polyolefin resin, and a silicone resin, may also be used in combination to an extent of not exceeding 50% by mass of the total amount of the binder. However, if the amount of the resin other than a fluorine-based polymer is greater than 50% by mass, weather resistance may decrease when the binder is used in a back sheet.

—Crosslinking Agent—

In the present invention, the specific polymer layer has a structural moiety derived from at least one crosslinking agent selected from carbodiimide-based compounds and oxazoline-based compounds. That is, the specific polymer layer is formed by indispensably using a specific crosslinking agent capable of cross-linking a binder component contained in the specific polymer layer. By allowing the specific polymer layer to have a structural moiety derived from such, a crosslinking agent, the adhesion after exposure to moisture and heat over time, specifically the adhesion to the polyester film which has been exposed in a hot and humid environment, as well as the interlayer adhesion can be further improved.

As the crosslinking agent, from the standpoint of ensuring excellent adhesion after exposure to moisture and heat over time, at least one crosslinking agent selected from carbodiimide-based compounds and oxazoline-based compounds is indispensably used. By using such crosslinking agent(s), when a flame treatment in which a silane compound is added to the flame or an atmospheric-pressure plasma treatment is performed as a surface treatment, the adhesion after exposure to moisture and heat over time can be further improved in a synergistic manner.

Further, in the present invention, a crosslinking agent other than a carbodiimide-based compound and an oxazoline-based compound may also be used in combination in the range which does not adversely affect the effects of the present invention. Examples of such other crosslinking agent include epoxy-based compounds, isocyanate-based compounds and melamine-based compounds.

Specific examples of the crosslinking agent of the oxazoline-based compound include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,41-dimethyl-2-oxazoline), 2,2′-p-phenylenebis-(2-oxazoline), 2,2′-m-phenylene-bis-(2-oxazoline), 2,2′-m-phenylene-bis-(4,4′-dimethyl-2-oxazoline), bis-(2-oxazolinylcyclohexane) sulfide, and bis-(2-oxazolinylnorbornane) sulfide. Furthermore, (co)polymers of these compounds are also used with preference.

As the crosslinking agent of the oxazoline-based compound, EPOCROS K2010E. EPOCROS K2020E, EPOCROS K2030E, EPOCROS WS-500, EPOCROS WS-700 (trade names, all manufactured by Nippon Shokubai co., Ltd.) and the like may also be used.

Specific examples of the crosslinking agent of the carbodiimide-based compound may include dicyclohexylmethane carbodiimide, tetramethylxylylene carbodiimide, dicyclohexylmethane carbodiimide, and the like. Further, the carbodiimide compounds described in JP-A No. 2009-235278 are also preferable. Specifically, as the crosslinking agent of the carbodiimide-based compound, commercially available products such as CARBODILITE SV-02, CARBODILITE V-02, CARBODILITE V-02-L2, CARBODILITE V-04, CARBODILITE E-01, or CARBODILITE E-02 (all trade names, manufactured by Nisshinbo Chemical, Inc.) can also be used.

In the specific polymer layer, the proportion by mass of the structural portion derived from the crosslinking agent relative to the binder including the fluorocarbon-based polymer is preferably from 0.5% by mass to 30% by mass, and more preferably from 2% by mass to 25% by mass. When the content of*the crosslinking agent is 0.5% by mass or higher, the specific polymer layer has more excellent strength and more excellent adhesiveness after a lapse of time under moisture and heat. When the content of the crosslinking agent is 30% by mass or lower, a further prolonged pot life of the coating liquid can be maintained.

—Surfactant—

The specific polymer layer may contain a surfactant.

As the surfactant; any known anionic or nonionic surfactant may be used. In the case of adding a surfactant, the amount of addition thereof is preferably 0.1 mg/m² to 15 mg/m², and more preferably 0.5 mg/m² to 5 mg/m². When the amount of addition of the surfactant is 0.1 mg/m⁵ or greater, the occurrence of cissing is suppressed, and satisfactory layer formation may be achieved. When the amount of addition is 15 mg/m² or less, the adhesion of the polymer support and the fluorine-containing polymer layer may be achieved satisfactorily.

—Filler—

The specific polymer layer may contain a filler. Examples of the filler that may be used include known fillers such as colloidal silica and titanium dioxide.

The amount of addition of the filler is preferably 20% by mass or less, and more preferably 15% by mass or less, with, respect to an amount of the binder component of the specific polymer layer. When the amount of addition of the filler is 20% by mass or less, the surface; state of the specific polymer layer may be maintained more satisfactorily, and adhesiveness with a polyester film may be improved.

(Thickness)

A thickness of the specific polymer layer is preferably 0.5 μm to 15 μm, more preferably 0.8 μm to 12 μm, and particularly preferably 1.0 μm to 10 μm. If the thickness of the specific polymer layer is 0.5 μm or thicker, durability of the outermost layer of the backsheet for a solar cell may be sufficiently achieved. On the other hand, if the thickness of the specific polymer layer is 15 μm or thicker, there may be a ease in which the adhesive force between the specific polymer layer and the polyester film is insufficient.

The specific polymer layer may be formed by applying a coating liquid at least containing the fluorine-based polymer and the crosslinking agent, on the polyester film base material, and drying the coating film thus formed. After drying, the specific polymer layer may be cured by heating or the like. There are no particular limitations on the coating method or the solvent of the coating liquid.

As the coating method, for example, a gravure coater or a bar coater may be used.

The coating liquid may further contain a solvent, and tire solvent may be water, or may be an organic solvent such as toluene or methyl ethyl ketone. One kind of a solvent may be used singly, or two or more kinds thereof may be used in mixture. However, a method of forming an aqueous coating liquid in which a binder component such as a fluorine-based polymer is dispersed in water and applying this aqueous coating liquid is preferred. In this ease, the proportion of water in the solvent is preferably 50% by mass or greater, and more preferably 80% by mass or greater. When the solvent contained in the coating liquid that forms the fluorine-containing polymer layer contains 50% by mass or more of water, the environmental burden is reduced, which is preferable.

(Position)

On the specific polymer layer, another layer may be further laminated; however, from the standpoints of durability improvement, weight reduction, thickness reduction, cost saving and the like, it is preferred that the specific polymer layer be the outermost layer. The term “outermost layer” used herein means a layer which constitutes the outermost layer in the backsheet according to the present invention.

It is preferred that the specific polymer layer be in direct contact with the treated surface of the polyester film without any adhesive agent or tackifier. The backsheet according to the present invention may be constituted only by the polyester film and the specific polymer layer, or may have other layer(s) selected as required on either or both of the polyester film and the specific polymer layer.

—Back Layer—

In cases where the specific polymer layer is constituted as a back layer, other components) such as various additives may also be incorporated as required. In a solar cell having a laminated structure of a cell-side substrate (mat is, a transparent substrate (such as a glass substrate) on the sunlight incident side/an element structural moiety containing a photovoltaic element)/a solar cell backsheet, the back layer is a back surface protection layer arranged on the opposite side of the surface facing the above-described cell-side substrate of the polymer base material (support), and the back layer may have a single-layer structure or a laminated structure of two or more layers. By containing a fluorine-based polymer and a structural moiety derived from a crosslinking agent, the specific polymer layer can have an improved adhesion with the polyester film base material and, in cases where the back layer is constituted by two or more layers, the interlayer adhesion can be improved. Further, degradation resistance in a hot and humid environment can be attained. Therefore, in a preferred mode, the back layer, which is the specific polymer layer, contains a layer arranged as the outermost layer.

In cases where two or more back layers are arranged, all of the back layers may be the specific polymer layer, or only one of the back layers may be the specific polymer layer.

In such cases, from the standpoint of improving the adhesion durability in a hot and humid environment, it is preferred that at least the back layer in contact with the polyester film base material (first back layer) be constituted by the specific polymer layer.

Examples of additional components which may be contained in the back layer include a surfactant, a filler, and the like, as described below. Further, the back layer may contain pigments which are used in the colored layer. Details and preferable embodiments of these additional components and pigments are described below.

—Colored Layer—

In a case in which the specific polymer layer according to the present invention is constructed as a colored layer (preferably, as a reflective layer), the colored layer further contains a pigment, in addition to the fluorocarbon-based polymer and the crosslinked structural moiety derived from the specific crosslinking agent. The colored layer may further include additional components such as various additives, as necessary.

The functions of the colored layer may include, firstly, an enhancement of the power generation efficiency of solar cell modules by reflecting a portion of incident light which passes through a photovoltaic cell and reaches the back sheet without being used in the power generation, to return the portion of light to the photovoltaic cell; and secondly, an enhancement of the decorative properties of the external appearance when the solar cell module is viewed from the side through which sunlight enters (front surface side). Generally, when a solar cell modules is viewed from the front surface side, the back sheet is seen around the photovoltaic cell. Thus, when a colored layer is provided in the back sheets, the decorative properties of the back sheet are improved, and thereby the appearance may be improved.

(Pigment)

The colored layer in the invention contains at least one pigment.

As the pigment, for example, an inorganic pigment such as titanium dioxide, barium sulfate, silicon oxide, aluminum oxide, magnesium oxide, calcium carbonate, kaolin, talc, ultramarine blue, Prussian blue, or carbon black; or an organic pigment such as phthalocyanine blue or phthalocyanine green can be appropriately selected and incorporated.

In the case where a polymer layer is constructed as a reflective layer which reflects the light that has entered a solar cell and passed through the photovoltaic cell, and returns the light to the photovoltaic cell, it is preferable that the colored layer contain a white pigment among the pigments. Preferable examples of the white pigment include titanium dioxide, barium sulfate, silicon oxide, aluminum oxide, magnesium oxide, calcium carbonate, kaolin, and talc.

The content of the pigment in the colored layer is preferably in the range of 2.5 g/m² to 8.5 g/m². When the content of the pigment is 2.5 g/m² or greater, necessary coloration may be achieved, and a desired reflection ratio or decorative properties may be effectively imparted to the colored layer. Furthermore, when the content of the pigment in the colored layer is 8.5 g/m² or less, the surface state of the colored layer may be easily maintained satisfactory, and the film strength is more excellent. Among these values, the content of the pigment is more preferably in the range of 4.5 g/m³ to 8.0 g/m².

The volume average particle diameter of the pigment is preferably 0.03 μm to 0.8 μm, and more preferably about 0.15 μm to 0.5 μm. When the average particle diameter is in the range mentioned above, the efficiency of light reflection is high. The average particle diameter is a value measured with a laser diffraction/scattering type particle diameter distribution measuring apparatus LA95G (trade name, manufactured by Horiba, Ltd.).

When the polymer layer constitutes the colored layer, the content of the binder component (including the fluorine-based polymer) is preferably in the range of 15% by mass to 200% by mass, and more preferably in the range of 17% by mass to 100% by mass, based on the content of the pigment. When the content of the binder is 15% by mass or more, the strength of the colored layer is sufficiently obtained, and when the content is 200% by mass or less, the reflectance or decorativeness may be maintained satisfactorily.

—Additives—

The specific polymer layer may further contain a surfactant, a filler, and the like as necessary.

The surfactant such as known anionic or nonionic surfactants can be used. When a surfactant is added in the polymer layer, the amount added is preferably 0.1 mg/m² to 15 mg/m², and more preferably 0.5 mg/m² to 5 mg/m². When the amount of the surfactant added is 0.1 mg/m² or greater, the occurrence of cissing is suppressed, and satisfactory layer formation may be achieved. When the amount added is 15 mg/m² or less, the adhesion can be satisfactorily achieved.

The polymer layer may further contain a filler. The amount of addition of the filler is preferably 20% by mass or less, and more preferably 15% by mass or less with respect to the content of the binder in the polymer layer. When the amount of addition of the filler is 20% by mass or less, the surface state of the polymer layer may be maintained more satisfactorily.

—Physical Properties—

In the case of preparing a reflective layer by adding a white pigment as a pigment to the colored layer, it is preferable that a reflectance of light having a wavelength of 550 nm on the surface of the side having thereon the colored layer and a readily-adhesive layer is 75% or greater. Note that, a light reflectance is a ratio of the amount of light that enters through, the surface of the readily-adhesive layer, is reflected by the reflective layer, and exits again through the readily-adhesive layer, relative the amount of incident light. Here, the light having a wavelength of 550 nm is used as the light having a representative wavelength.

When the light reflectance is 75% or greater, light that has passed through the cell and has entered into inside may be effectively returned to the cell, and thus, a large effect of enhancing the power generation efficiency may be achieved. The light reflectance can be adjusted to 75% or greater, by controlling the content of the colorant in the range of from 2.5 g/m² to 30 g/m².

(Additional Functional Layer)

The backsheet for a solar cell of the present invention may have additional functional layers (other polymer layer and the like), other than the polyester film base material (support) and the specific polymer layer. As the additional functional layer, a colored layer (reflective layer) or a readily-adhesive layer may be provided.

Further, the solar cell backsheet according to the present invention may also contain other various functional layers selected as required on either or both of the surface of the above-described polyester film base material and the surface of the above-described specific polymer layer. The solar cell, backsheet may contain only one of such other layers, or two or more of such other layers.

Among such functional layers, it is preferred that the backsheet according to the present invention take a mode in which a colored layer (preferably a white layer (reflective layer)) is laminated on the above-described polyester film base material or a mode in which a readily-adhesive layer and a white layer (reflective layer) are laminated on either surface of the above-described base material. Further, it is also preferred that the backsheet according to the present invention take a mode in which a readily-adhesive layer and a white layer (reflective layer) are laminated onto either surface of the above-described polyester film base material by coating. Among these modes, it is preferred that a colored layer be arranged on the side of the polyester film base material opposite to the surface on which the specific polymer layer is arranged. Further, in the solar cell backsheet according to the present invention, it is preferred that the functional layer(s) be formed on the side which is preferably pasted with a sealing material sealing a photovoltaic element. That is, in the solar cell backsheet according to the present invention, it is preferred that the functional layer(s) be formed on the base material surface on which the specific polymer layer is not formed and that the above-described polyester film base material be arranged, on the side of the cell-side substrate on which a photovoltaic element is sealed with a sealing material.

In the solar cell protection sheet according to the present invention, from the standpoint of improving the weather resistance, it is preferred that the above-described specific polymer layer be the outermost layer and that, when incorporated into a solar cell module, the specific polymer layer containing a fluorine-based polymer be arranged to be the outermost layer.

<Colored Layer>

In the backsheet according to the present invention, in addition to the aspect in which the specific polymer layer is formed as a colored layer, a colored layer (preferably a reflective layer) containing substantially no fluorine-based polymer may be arranged as well. In this case, the colored layer contains at least a polymer component other than the above-described fluorine-based polymer and a pigment and, as required, can be constituted with other components) such as various additives.

Here, the details of the pigment and various additives are as described in the above for the case where the specific polymer layer is formed as a colored layer. The polymer component other than the fluorine-based polymer is not particularly limited and can be selected as appropriate in accordance with the purpose and the like thereof.

The phrase “containing substantially no fluorine-based polymer” used in the above means that a fluorine-based polymer is not positively contained in the colored layer. Specifically, the phrase means that the content of fluorine-based polymer in the colored layer is 15% by mass or less, and it is preferred that the colored layer contain no fluorine-based polymer (the content of fluorine-based polymer is 0 (zero) % by mass.

—Readily-Adhesive Layer—

The back sheet in the invention may be further provided with a readily-adhesive layer. The readily-adhesive layer is a layer intended for strong adhesion of the back sheet to a sealing material that seals the photovoltaic element (hereinafter, also referred to as “power generating element”) of the substrate on the cell side (main body of the cell). The readily-adhesive layer may be constituted with the specific polymer.

The readily-adhesive layer can be constructed by using a binder and inorganic fine particles, and may further include, as necessary, additional components such as additives. It is preferable that the readily-adhesive layer is constituted so as to have an adhesive power of 10 N/cm or more (preferably 20 N/cm or more) with respect to the sealing material (for example, ethylene-vinyl acetate (EVA) copolymer) that seals the power generation elements of the cell-side base board. When the adhesive power is 10 N/cm or more, moisture and heat resistance capable of maintaining the adhesiveness may be easily obtained.

Note that, the adhesion is may be adjusted by using a method of regulating the amount of the binder and inorganic fine particles in the readily-adhesive layer, a method of applying a corona treatment to a face that is bonded to the sealant of the backsheet, or other methods.

—Binder—

The readily-adhesive layer may contain at least one binder. When the specific polymer layer is formed with the readily-adhesive layer, a binder thereof includes a fluorine-based polymer.

Examples of the binder that is suitable for the readily-adhesive layer include a polyester, a polyurethane, a fluorine-based resin, an acrylic resin, and a polyolefin. Among them, an acrylic resin or a polyolefin is preferable from the viewpoint of durability. Furthermore, a composite resin of acrylic resin ingredient and silicone resin ingredient is also preferable as the acrylic resin.

Preferable examples of the binder include, as specific examples of the fluorine-based resin, OBBLIGATO SW0011F (trade names, manufactured by AGC COAT-TECH, Co. Ltd.), ZEFFLE (trade names, manufactured by DAIKIN, INDUSTRIES Ltd.), as specific examples of the polyolefin, CHEMIPEARL S-3.20 and S-75N (trade names, all manufactured by Mitsui Chemicals, Inc.); as specific examples of the acrylic resin, JURYMER ET-410 and SEK-301 (trade names, all manufactured by Nihon Junyaku Co., Ltd.); and as specific examples of the composite resin of acrylic resin ingredient and silicone resin ingredient, CERANATE WSA1060 and WSA1070 (trade names, ail manufactured by DIC Corp.), H7620, H7630 and H7650 (trade names, all manufactured by Asahi Kasei Chemicals Corp.).

The content of the binder in the readily-adhesive layer is preferably in the range of 0.05 g/m² to 5 g/m². Inter alia, the content is more preferably in the range of 0.08 g/m² to 3 g/m². If the content of the binder is 0.05 g/m² or more, a desired adhesive power is easily obtained, and if the content is 5 g/m² or less, a satisfactory surface state can be obtained.

—Fine particles—

The readily-adhesive layer may contain at least one kind of inorganic fine particles.

Examples of the inorganic fine particles include fine particles of silica, calcium carbonate, magnesium oxide, magnesium carbonate and tin oxide. Among them, the fine particles of tin oxide and silica are preferable from the viewpoint that the decrease in adhesiveness is small when the readily-adhesive layer is exposed to a hot and humid atmosphere.

The particle size of the inorganic fine particles is preferably about 10 ran to 700 nm, and more preferably about 20 nm to 300 nm, as the volume average particle size. When the particle size is in this range, more satisfactory adhesiveness can be obtained. The particle size is a value measured with a laser diffraction/scattering type particle size distribution analyzer LA950 (trade name, manufactured by Horiba, Ltd.).

There are no particular limitations on the shape of the inorganic fine particles, and the inorganic fine particles having any of a spherical shape, an amorphous shape, a needle shape and the like can be used.

A content of the inorganic fine particles is in the range of 5% by mass to 400% by mass, based on the binder in the readily-adhesive layer. If the content of the inorganic fine particles is less than 5% by mass, satisfactory adhesiveness cannot be retained when the readily-adhesive layer is exposed to a hot and humid atmosphere, and if the content is greater than 400% by mass, the surface state of the readily-adhesive layer is deteriorated.

Inter alia, the content of the inorganic fine particles is preferably in the range of 50% by mass to 300% by mass.

<Crosslinking Agent>

The readily-adhesive layer can contain at least one crosslinking agent.

Examples of the crosslinking agent that is suitable for the readily-adhesive layer include crosslinking agents such as epoxy-based compound, isocyanate-based compound, melamine-based compound, carbodiimide-based compound and oxazoline-based compound. In a case where the specific polymer layer is formed with the readily-adhesive layer, at least one crosslinking agent selected from carbodiimide-based compound and oxazoline-based compound is used therein. Among them, from the viewpoint of securing adhesiveness after a lapse of time under a circumstance of heat and moisture, an oxazoline-based crosslinking agent is particularly preferable.

As the specific examples of the oxazoline-based crosslinking agent, the same crosslinking agents as ones above described usable for the specific polymer layer are also preferably exemplified for readily-adhesive layer.

A content of the crosslinking agent in the readily-adhesive layer is preferably 5% by mass to 50% by mass based on the binder in the readily-adhesive layer, and inter alia, more preferably 20% by mass to 40% by mass. When the content of the crosslinking agent is 5% by mass or greater, a satisfactory crosslinking effect is obtained, and the strength of the readily-adhesive layer and adhesiveness of the readily-adhesive layer between the adjacent layer can be maintained. When the content is 50% by mass or less, a prolonged pot life of the coating liquid can be maintained.

—Additives—

The readily-adhesive layer according to the invention may optionally contain a known matting agent such as polystyrene, polymethyl methacrylate or silica; a known anionic or nonionic surfactant; and the like.

—Method of Forming Readily-Adhesive Layer—

The formation of the readily-adhesive layer may be carried out by using a method of pasting a polymer sheet having easy adhesiveness to a substrate, or a method based on coating. Among them, the method based on coating is preferable from the viewpoints that the method is convenient, and it is possible to form a uniform thin film. In regard to the coating method, known coating methods using, for example, a gravure coaler or a bar coater can be used.

The coating solvent used in the preparation of the coating liquid may be water, or may be an organic solvent such as toluene or methyl ethyl ketone. The coating solvent may be used singularly, or in a combination of two or more kinds thereof.

There are no particular limitations on the thickness of the readily-adhesive layer, but the thickness is usually preferably 0.05 μm to 8 μm, and more preferably in the range of 0.1 μm to 5 μm. When the thickness of the readily-adhesive layer is 0.05 μm or thicker, the necessary adhesiveness can be suitably obtained, and when the thickness is 8 μm or thinner, the surface state becomes more satisfactory.

—Physical Properties—

Further, the backsheet for a solar cell of the invention preferably has an adhesive power to the sealing material after storage for 48 hours under an atmosphere of 120° C. and 100% RH of 75% or more, with respect to the adhesive power to the sealing material before storage. As described above, the backsheet for a solar cell of the invention has a readily-adhesive layer that includes a predetermined amount of a binder and a predetermined amount of inorganic fine particles with respect to the binder and has an adhesive power of 10 N/cm or more to the EVA sealing material and therefore, even after the storage described above, an adhesive power of 75% or more of the adhesive power before storage is obtained. Accordingly, when prepared as a solar cell module, peeling of the backsheet and deterioration in power generation performance due to the peeling are suppressed, and the long-term durability is further enhanced.

Production of Solar Cell Backsheet

As described in the above, the solar cell backsheet according to the present invention may be produced by any method as long as the method is capable of forming, on a polyester film base material serving as a base material, a specific polymer layer and other layer arranged as required.

In the present invention, a solar cell backsheet can be suitably produced by a method which includes the steps of; coating a liquid containing a fluorine-based polymer and a crosslinking agent (and, as required, a coating liquid for forming a readily-adhesive layer and the like) onto a polyester film base material; and forming at least one polymer layer including a specific polymer layer (the method of producing a solar cell backsheet according to the present invention).

It is noted here that the coating liquid used for forming a specific polymer layer contains, as described in the above, at least a fluorine-based polymer and a crosslinking agent. The details of the polymer film base material and the components constituting the respective coating liquids are as described in the above.

The suitable coating method is also as described in the above and, for example, a gravure coater or a bar coater can be employed. Further, in the coating step of the present invention, a coating liquid for forming a polymer layer can be coated directly onto the surface of the polyester film base material so as to form a specific polymer layer and other polymer layer(s) (such as a colored layer (preferably a reflective layer)) on the polyester film base material.

Formation of the polymer layer can be carried out by a method of pasting a polymer sheet onto the polymer base material, a method of co-extruding the polymer layer at the time of forming the polymer base material, a method based on coating, or the like. Among them, a method based on coating is preferable from the viewpoints mat the method is convenient, and is possible to form a uniform thin film. In the case of forming the polymer layer by coating, in regard to the coating method, known coating methods using, for example, a gravure coater or a bar coater can be used.

The coating liquid may be an aqueous system using water as a coating solvent or a solvent-based system using an organic solvent such as toluene, methyl ethyl ketone or the like. Among them, from the viewpoint of environmental load, it is preferable to use water as the solvent. The coating solvent may be used singularly, or in a combination of two or more kinds thereof.

The coating liquid for polymer layer is preferably an aqueous coating liquid in which 50% by mass or more, preferable 60% by mass or more, of the solvent contained in the coating liquid is water. Aqueous coating liquids are preferable in view of environmental load, and when the proportion of water is 50% by mass or more, it is advantageous since environmental load becomes particularly small. From the viewpoint of environmental load, a larger proportion of water in the coating liquid for polymer layer is desirable, and the case of containing water in an amount of 90% by mass or more of the total amount of solvents is more preferable.

After coating, a drying step in which drying is carried out under desired conditions may be provided.

<Soar Cell Module>

The solar cell module of the present invention is constituted by providing the above-described backsheet for a solar cell of the invention, or a backsheet for a solar cell produced by the above-described method of producing a backsheet for a solar cell. In a preferable embodiment of the present invention, the solar cell module is constituted such that a solar cell element that converts the light energy of sunlight to electrical energy is disposed between a transparent front base board, through which sunlight enters, and the above-described backsheet for a solar cell of the invention, and the solar cell element is sealed and adhered between the front base board and the backsheet using a sealing material such as an ethylene-vinyl acetate sealing material. That is, a cell structural portion having a solar cell element and a sealing material that seals the solar cell element is provided between the front base board and the backsheet.

Regarding members other than the solar cell module, the solar cells, and the backsheet, they are described in detail in “Taiyoko Hatsuden System Kosei Zairyo” (under the supervision of Eiichi Sugimoto, published by Kogyo Chosakai Publishing, Inc., 2008), for example.

The transparent base board may only has a light transparency to such an extent that sunlight is allowed to pass through it, and may be selected appropriately from base materials that allow light to transmit therethrough. From the viewpoint of power generation efficiency, a transparent base board that has a higher light transmittance is more preferable. For such a transparent base board, a glass base board, a transparent resin such as acrylic resin and the like may be suitably used, for example.

For the solar cell elements, various kinds of known solar cell elements may be used, including; solar cells based on silicon such as single crystal silicon, polycrystalline silicon, or amorphous silicon; and solar cells based on a III-V or II-VI compound semiconductor such as copper-indium-gallium-selenium, copper-indium-selenium, cadmium-tellurium, or gallium-arsenic.

<Evaluation Methods>

The evaluation methods for the characteristics that are applied to tire present specification, including the Examples of the invention that will be described below, will be shown below.

(1) Intrinsic Viscosity

A film is dissolved in ortho-chlorophenol, and the solution viscosity is measured at 25° C. Thus, the intrinsic viscosity is obtained from the solution viscosity based on the following formula:

ηsp/C=[η]+K[η]2·C

Wherein ηsp=ηsn/ηsv−1; ηsn represents a solution viscosity; ηsv represents a solvent viscosity; C represents the dissolved polymer mass dissolved per 100 ml of the solvent (in the present measurement, set to 1 g/100 ml); K represents the Huggins constant (set to 0.343); and the solution viscosity and the solvent viscosity are measured using an Ostwald viscometer.

(2) Terminal Carboxyl Group Concentration

0.5 g of a polyester film is dissolved in o-cresol, and the potential difference is measured by potentiometric titration using potassium hydroxide. Thus, the terminal carboxyl group concentration is determined.

—Minute Endothermic Peak Temperature Tmeta (° C.) Determined, by Differential Scanning Calorimetry (DSC)—

The minute endothermic peak temperature Tmeta (*C) was measured using a differential scanning calorimetric apparatus “ROBOT DSC-RDC220” (trade name, manufactured by Seiko Instruments and Electronics Co., Ltd.) in accordance with JIS K7122-1987 (by reference to JIS Handbook, 1999 edition), and the data analysis was conducted using a disc session “SSC/5200” (trade name). Specifically, 5 mg of the film were weighed and set in a sample pan, and measurement was conducted while raising the temperature from 25° C. to 300° C. at a temperature increase rate of 20° C./min.

The temperature of a minute endothermic peak appearing before the crystalline melting peak in the differential scanning calorimetric chart thus obtained is designated as Tmeta (° C.). In a case in which a minute endothermic peak was hardly observed, the vicinity of the peak was magnified at the data analysis unit, and the peak was read out.

The method for reading the graph of a minute endothermic peak is not described in JIS; however, graph reading was carried out according to the following method.

First, a straight line was drawn between the value at 135° C. and the value at 155° C., and the area between the straight line and the graph curve on the endotherm side was determined. Similarly, the areas at 17 pairs of points of 140° C. and 160° C., 145° C. and 165° C., 150° C. and 170° C., 155° C. and 175° C., 160° C. and 180° C., 165° C. and 185° C., 170° C. and 190° C., 175° C. and 195° C., 180° C. and 200° C., 185° C. and 205° C., 190° C. and 210° C., 195° C. and 215° C. 200° C. and 220° C., 205° C. and 225° C., 210° C. and 230° C., 215° C. and 235° C., and 220° C. and 240° C. were determined. Since the amount of heat absorption of a minute peak is generally from 0.2 J/g to 5.0 J/g, only the data in which the area was within the range of from 0.2 J/g to 5.0 J/g were employed as effective data. Among the 18 area data in total, the peak temperature of an endothermic peak which is in a temperature region of a datum that shows the largest area and is an effective datum is designated as Tmeta (° C.). In a case in which there are not any effective data, it is determined that Tmeta (° C.) is absent.

—Thermal Shrinkage Ratio (MD/TD)—

A sample having a width of 10 mm and a distance between marked lines of about 100 mm was heat treated, according to JIS-C2318 (2007), at a temperature of 150° C. and under a load of 0.5 g for 30 minutes. The distance between the marked lines was measured before and after the heat treatment, using a thermal shrinkage ratio measuring device (trade name: No. AMM-1 machine, manufactured by Techno Needs Co., Ltd.), and the thermal shrinkage ratio was calculated according to the following Equation.

Rts(%)={(L₀−L)/L₀}×100

Rts: Thermal shrinkage ratio

L₀: Distance between marked lines before heat treatment

L: Distance between marked lines after heat treatment

—Plane Orientation Coefficient (f_{PO})—

The film refractive index was measured using an Abbe refractometer TYPE 4T (trade name, manufactured by Atago Co., Ltd.) and using a sodium lamp as the light source.

f_{PO}=(nMD+nTD)/2−nZD (A)

In Equation (A) above, nMD represents the refractive index in the longitudinal direction (MD) of the film; nTD represents the refractive index in the orthogonal direction (TD) of the film; and nZD represents the refractive index in the film thickness direction.

—Content of Phosphorus Atoms—

The content of phosphorus atoms was measured by a fluorescent X-ray method (trade name: ZSX 100E, manufactured by Rigaku Corp.)

(7) Analysis of Composition of Polyester

A polyester is hydrolyzed using an alkali, the respective components are analyzed by gas chromatography or high performance liquid chromatography, and the composition ratios of the respective components are determined from the peak areas.

An example will be described in the following.

A dicarboxylic acid constituent component or a constituent component having carboxyl groups is measured by high performance liquid chromatography. The analysis may be carried out under known measurement conditions by a known method. The measurement conditions that are applied to the invention will be shown below.

Apparatus: SHIMADZU LC-10A

Column: YMC-PACK ODS-A 150×4.6 mm S—5 μm 120 A

Column temperature: 40° C.

Flow rate: 1.2 ml/min

Detector: UV 240 nm

Quantification of a diol constituent component or a constituent component having hydroxyl groups may be analysed by a known method using gas chromatography. The measurement conditions that are applied to the invention will be shown below.

Apparatus: SHIMADZU 9A (trade name, manufactured by Shimadzu Corp.)

Column: SUPELCOWAX-10 capillary column 30 m

Column temperature: 140° C. to 250° C. (temperature increase rate 5° C./min)

Flow rate: nitrogen 25 ml/min

Detector: FID

(8) Elongation Retention Ratio after Storage for 72 Hours Under Conditions of 125° C. and Moisture of 100%

Measurement of the breaking elongation is carried out according to ASTM-D882-97 (see ANNUAL BOOK OF ASTM STANDARDS, 1999 edition). A sample is cut to a size of 1 cm×20 cm, and the breaking elongation (initial) is measured by pulling the sample under the conditions of a distance between chucks of 5 cm, and a tensile speed of 300 mm/min. The measurement is made for five samples, and the average value is designated as breaking elongation (initial) A2.

Subsequently, a sample is cut to a size of 1 cm×20 cm, and the sample is treated for 72 hours under the conditions of 125° C. and a moisture of 100%, using a highly accelerated life testing apparatus (HAST apparatus) (trade name: PC-304R8D, manufactured by Hirayama Manufacturing Corp.). Subsequently, the breaking elongation of the sample after the treatment is measured according to ASTM-D882(1999)-97 (see ANNUAL BOOK OF ASTM STANDARDS, 1999 edition), as a breaking elongation (post-treatment) by pulling the sample under the conditions of a distance between chucks of 5 cm, and a tensile speed of 300 mm/min. The measurement is made for five samples, and the average value is designated as breaking elongation (post-treatment) A3.

The elongations at break A2 and A3 thus obtained are used to calculate the elongation retention ratio (Lr) by the following formula (3).

Lr(%)=A3/A2×100 (3)

Furthermore, the average elongation retention ratio (Lave) is calculated by the following formula (4),

Lave(%)=(LrMD+LrTD)/2 (4)

Here, LrMD represents an elongation retention ratio in the MD direction, and LrTD represents an elongation retention ratio in the TD direction.

(9) Specific Surface Resistance (R₀)

The specific surface resistance R₀ of a polyester film is measured using a digital ultra-high resistance microcurrent meter (trade name: R8340, manufactured by Advantest Corp.). However, when the specific surface resistance is 10⁶Ω/□ or less, a LORESTA EP (trade name, manufactured by Dia instruments Co., Ltd.) equipped with an ASP probe is used. Furthermore, measurement is made at any 10 sites within the film surface, and their average value is designated as the specific surface resistance R₀. A measurement sample which has been left to stand overnight in a room at 23° C. and 65% RH is used to make the measurement.

(10) Whiteness

Furthermore, whiteness degree (W) is calculated by the following formula using the following values measured with a colorimeter ND-300A (trade name, manufactured by NIPPON DENSHOKU INDUSTRIES Co., Ltd.)

W=100−[(100−L)²+a²+b²]^{1/2}

Here, W represents whiteness degree, L represents luminosity value, a represents chroma and b represents hue.

### EXAMPLES

The present invention will be further described in detail with reference to the following examples, but it should be construed that the present invention is in no way limited to those examples as long as not departing from the scope of the invention. Note that, “part(s)” and “%” in Examples are on the basis of mass.

Hereafter, a volume average particle size is measured with a laser diffraction/scattering type particle size distribution analyzer LA950 (trade name, manufactured by Horiba, Ltd.).

Production of Polyester Film Base Material

—Production of PET-1—

[Step 1]

100 parts of dimethyl terephthalate, trimethyl trimellitate (added to achieve a molar ratio of dimethyl terephthalate/trimethyl trimellitate=99.7/0.3), 57.5 parts of ethylene glycol, 0.06 parts of magnesium acetate, and 0.03 parts of antimony trioxide were melted at 150° C. in a nitrogen atmosphere, and while the mixture was stirred, the temperature was increased to 230° C. over 3 hours. Methanol was distilled off, and thus a transesterification reaction was completed.

[Step 2]

After completion of the transesterification reaction, an ethylene glycol solution prepared by dissolving 0.019 parts (equivalent to 1.9 mol/ton) of phosphoric acid and 0.027 parts (equivalent to 1.5 mol/ton) of sodium dihydrogen phosphate dihydrate in 0.5 parts of ethylene glycol, was added to the system.

[Step 3]

A polymerization reaction was carried out at an end-point temperature of 285° C. and a degree of vacuum of 0.1 Torr, and thus a polyester having an intrinsic viscosity of 0.54 and a number of terminal carboxyl groups of 13 eq/ton was obtained.

[Step 4]

The polyethylene terephthalate thus obtained was dried for 6 hours at 160° C. and was crystallized. Subsequently, solid state polymerization was carried out at 220° C. and at a degree of vacuum of 0.3 Torr for 9 hours, and thus a polyester having 0.15% by mole of the constituent component (p), an intrinsic viscosity of 0.90, a number of terminal carboxyl groups of 12 eq/ton, a melting point of 255° C., and a glass transition temperature Tg of 83° C. was obtained.

[Step 5]

One part of a polycarbodiimide (trade name: STABAXOL P100”, manufactured by Rhein Chemie Rheinau GmbH) was added to 99 parts of the polyester obtained in Step 4, and the mixture was compounded.

[Step 6]

The compounded product obtained as described above was subjected to drying under reduced pressure for 2 hours under the conditions of a temperature of 180° C. and a degree of vacuum of 0.5 mmHg, and the dried product was supplied to an extruder which had been heated to 295° C. Foreign materials were filtered using a 50-μm cutoff filter, and then the compounded product was introduced into a T-die nozzle. Subsequently, the compounded product was extruded through the T-die nozzle into a sheet form, and thus a molten single-layer sheet was obtained. The molten single-layer sheet was adhered onto a drum which had been maintained at a surface temperature of 20° C., by an electrostatic application method, and the molten single-layer sheet was cooled and solidified. Thus, an unstretched single layer film was obtained.

[Step 7]

Subsequently, the unstretched single-layer film thus obtained was preheated using a group of heated rolls, and then MD stretching 1 was carried out to 1.8 times at a temperature of 80° C., followed by MD stretching 2 to 2.3 times at a temperature of 95° C. Stretching was carried out to 4.1 times in total in the longitudinal direction (MD), and then the film was cooled with a group of rolls at a temperature of 25° C. Thus, a uniaxially stretched film was obtained. While two edges of the uniaxially stretched film thus obtained were clamped with clips, the uniaxially stretched film was led into a preheating zone at a temperature of 95° C. in a tenter, and subsequently, the film was continuously stretched to 4.0 times in the width direction (TD), which was perpendicular to the longitudinal direction, in a heating zone at a temperature of 100*0.

[Step 8]

Subsequently, the film was subjected to a heat treatment for 20 seconds at a temperature of 205° C. (first heat treatment temperature) in a heat treatment zone in the tenter. Subsequently, the film was relaxed at a relaxation ratio of 3% in the width direction (TD) at a temperature of 180° C., and by reducing the clip interval of the tenter, the film was relaxed at a relaxation ratio of 1.5% in the longitudinal direction (MD). Subsequently, the film was uniformly cooled to 25° C., and then was rolled. Thus, a biaxially stretched polyester film. (PET-1) having a thickness of 250 μm was obtained.

Note that, the relaxation ratio can be calculated according to the following Formula (c), when designating the length of the polyester film before relaxation as La, and designating the length of the polyester film after relaxation as Lb.

100×(La−Lb)/La Formula (c)

La and Lb in the width direction of the polyester film, and La and Lb in the longitudinal direction of the polyester film are defined as described below.

[Width Direction]

When a polyester film is stretched by applying tension using a tenter, the maximum width of the polyester film at the time of stretching is designated, as the length of the polyester film before relaxation La. Further, the width of the polyester film after releasing the tension (relaxing) and taking the polyester film out from the tenter is designated as the length of the polyester film after relaxation Lb.

[Longitudinal Direction]

When a polyester film is stretched by applying tension using a tenter, the polyester film at the time of stretching is marked at two points in the longitudinal direction, and the distance between the two points is designated as the length of the polyester film before relaxation La. Further, the distance between the two points after releasing the tension (relaxing) and taking the polyester film out from the tenter is designated as the length of the polyester film after relaxation Lb.

The results of an evaluation of the characteristics of PET-1 are presented below.
Content of terminal carboxyl groups: 5 eq/t
Tmeta: 190° C.
Average elongation retention ratio: 50%
Plane orientation coefficient: 0.170
Intrinsic viscosity: 0.75 dL/g
Thermal shrinkage ratio (MD/TD): 0.4%/0.2%
Content of constituent component (p): 0.15 mol %
Buffering agent: Sodium dihydrogen phosphate 1.5 mol/t
Terminal blocking agent: Polycarbodiimide 1 wt %
Content of phosphorus atoms: 230 ppm.

—Production of PET-2—

[Step 1]

To a mixture of 100 parts of dimethyl terephthalate and 60.0 parts of ethylene glycol, 0.08 parts of calcium acetate and 0.03 parts of antimony trioxide were added, and while the mixture was heated to elevate the temperature thereof in a conventional manner, and thus a transesterification reaction was performed.

[Step 2]

After completion of the transesterification reaction, an ethylene glycol solution prepared by dissolving 0.019 parts (equivalent to 1.9 mol/ton) of phosphoric acid and 0.027 parts (equivalent to 1.5 mol/ton) of sodium dihydrogen phosphate dihydrate in 0.5 parts of ethylene glycol, was added to the system.

[Step 3]

A polymerization reaction was carried out at an end-point temperature of 285° C. and a degree of vacuum of 0.1 Torr, and thus a polyethylene terephthalate having an intrinsic viscosity of 0.52 and a number of terminal carboxyl groups of 13 eq/ton was obtained.

[Step 4]

The polyethylene terephthalate thus obtained was dried for 6 hours at 160° C. and was crystallized. Subsequently, solid state polymerization was carried out at 230° C. and at a degree of vacuum of 0.5 Torr for 20 hours, and thus a polyester having 0.15% by mole of the constituent component (p), an intrinsic viscosity of 0.79, a number of terminal carboxyl groups of 10.5 eq/ton, a melting point of 255° C., and a glass transition temperature Tg of 83° C. was obtained.

[Step 5]

One part of a polycarbodiimide (trade name: STABAXOL P100”, manufactured by Rhein Chemie Rheinau GmbH) was added to 99 parts of the polyester obtained in Step 4, and the mixture was compounded.

[Step 6]

The compounded product obtained as described above was subjected to drying under reduced pressure for 2 hours under the conditions of a temperature of 180° C. and a degree of vacuum of 0.5 mmHg, and the dried product was supplied to an extruder which had been heated to 295° C. Foreign materials were filtered using a 50-μm cutoff filter, and then the compounded product was introduced into a T-die nozzle. Subsequently, the compounded product was extruded through the T-die nozzle into a sheet form, and thus a molten single-layer sheet was obtained. The molten single-layer sheet was adhered onto a drum which had been maintained at a surface temperature of 20° C., by an electrostatic application method, and the molten single-layer sheet was cooled and solidified. Thus, an unstretched single layer film was obtained.

[Step 7]

Subsequently, the unstretched single-layer film thus obtained was preheated using a group of heated rolls, and then MD stretching 1 was carried out to 1.8 times at a temperature of 80° C., followed by MD stretching 2 to 2.3 times at a temperature of 95° C. Stretching was carried out to 4.1 times in total in the longitudinal direction (MD), and then the film was cooled with a group of rolls at a temperature of 25° C. Thus, a uniaxially stretched film was obtained. While two edges of the uniaxially stretched film thus obtained were clamped with clips, the uniaxially stretched film was led into a preheating zone at a temperature of 95° C. in a tenter, and subsequently, the film was continuously stretched to 4.0 times in the width direction (TD), which was perpendicular to the longitudinal direction, in a heating zone at a temperature of 100° C.

[Step 8]

Subsequently, the film was subjected to a heat treatment for 20 seconds at a temperature of 205° C. (first heat treatment temperature) in a heat treatment zone in the tenter. Subsequently, the film was relaxed at a relaxation ratio of 3% in the width direction (TD) at a temperature of 180° C., and by reducing the clip interval of the tenter, the film was relaxed at a relaxation ratio of 1.5% in fee longitudinal direction (MD). Subsequently, the film was uniformly cooled to 25° C., and then was rolled. Thus, a biaxially stretched polyester film (PET-2) having a thickness of 250 μm was obtained.

The results of an evaluation of the characteristics of PET-2 are presented below.
Content of terminal carboxyl groups: 7 eq/ton
Tmeta: 180° C.
Average elongation retention ratio: 35%
Plane orientation coefficient: 0.167
Intrinsic viscosity: 0.70 dl/g
Thermal shrinkage ratio (MD/TD): 0.6%/0.2%
Content of constituent component (p): none
Buffering agent: Sodium dihydrogen phosphate 1.5 mol/ton
Terminal blocking agent: Polycarbodiimide 1% by mass
Content of phosphorus atoms: 230 ppm

—Production of PET-3—

A biaxially stretched polyester film (PET-3) was produced in a manner substantially similar to the method used for PET-1, except that the sodium dihydrogen phosphate dihydrate used in the [Step 2] of the method for producing PET-1 was not added.

The characteristics of PET-3 were evaluated, and as compared with PET-1, the average elongation retention ratio changed to 40%, and the content of phosphorus atoms changed to 150 ppm.

—Production of PET-4—

A biaxially stretched polyester film (PET-4) was produced in a manner substantially similar to the method used for PET-1, except that [Step 5] of the method for producing PET-1 was not performed.

The characteristics of PET-4 were evaluated, and as compared with PET-1, the average elongation retention ratio changed to 25%, and the content of terminal carboxyl groups changed to 12 eq/ton.

—Production of PET-A—

A biaxially stretched polyester film (PET-A) was produced in a manner substantially similar to the method used for PET-1, except that in [Step 8] of the method for producing PET-1, the first heat treatment temperature was changed to 230° C.

The characteristics of PET-A were evaluated, and as compared with PET-1, Tmeta changed to 225° C., and the average elongation retention ratio changed to 7%.

—Production of substrate PET-B—

[Step 1]—Esterification—

A slurry of 100 parts of high purity terephthalic acid (manufactured by Mitsui Chemicals, Inc.) and 45 parts of ethylene glycol (manufactured by Nippon Shokubai Co., Ltd.) was sequentially supplied over 4 hours into an esterification reaction tank which had been previously charged with about 123 kg of bis(hydroxyethyl) terephthalate and was maintained at a temperature of 250° C. and at a pressure of 1.2×10⁵ Pa. Even after the completion of supply, the esterification reaction was performed for another one hour. Thereafter, 123 kg of the esterification reaction product thus obtained was transferred to a polycondensation reaction tank.

[Step 2]

—Production of Polymer Pellet—

Subsequently, to the polycondensation reaction tank to which the esterification reaction product was transferred, ethylene glycol was added in an amount of 0.3% by mass relative to the resulting polymer. After stirring the resulting mixture for 5 minutes, ethylene glycol solutions of cobalt acetate and manganese acetate were added such that the amount of elemental cobalt and that of elemental manganese became 30 ppm and 15 ppm, respectively, in the resulting polymer. After stirring the resultant for another 5 minutes, an ethylene glycol solution containing 2% by mass of a titanium alkoxide compound was added such that the amount of elemental titanium became 5 ppm in the resulting polymer. Five minutes later, an ethylene glycol solution containing 10% by mass of ethyl diethylphosphonoacetate was further added such that the amount of elemental phosphorus became 5 ppm in the resulting polymer. Then, while stirring the resulting low-molecular-weight polymer at 30 rpm, the temperature of the reaction system was gradually raised from 250° C. to 285° C. and the pressure was lowered to 40 Pa. The times for the reaction system to reach the final temperature and to reach the final pressure were both set to be 60 minutes. Once the stirring torque reached a prescribed value, the reaction system was purged with nitrogen and the pressure was restored to normal pressure, thereby terminating the polycondensation reaction. Thereafter, the resultant was ejected into cold water in the form of a strand and immediately cut to produce a polymer pellet (about 3 mm in diameter and about 7 mm in length). Here, the time required for the stirring torque to reach the prescribed value after the start of the pressure reduction was 3 hours.

It is noted here that, as the above-described titanium alkoxide compound, the titanium alkoxide (Ti content=4.44% by mass) which was synthesized in Example 1 described in the paragraph [0083] of JP-A No. 2005-340616 was employed.

[Step 3]

—Solid State Polymerization—

The thus obtained pellet was incubated at 220° C. for 30 hours in a vacuum vessel whose pressure was maintained at 40 Pa, thereby performing solid state polymerization.

[Step 4]

—Preparation of Film-Form Polymer Base Material—

After the pellet: was subjected to solid state polymerization in the above-described manner, the resulting pellet was melted at 280° C. and east onto a metal drum to form an unstretched film of about 3 mm in thickness.

Then, the thus obtained unstretched film was preheated with a group of heat rolls and subsequently subjected to a L1-times MD stretching 1 at a temperature of 80° C., followed by a 2.3-times MD stretching 2 at a temperature of 95° C. The film was thus stretched by a total of 4.1 times in the longitudinal direction (MD direction), and the resulting film was cooled with a group of rolls at a temperature of 25° C. to obtain a uniaxially stretched film. With both ends of the thus obtained uniaxially stretched film being clamped with clips, the uniaxially stretched film was introduced to a 95° C. preheating zone in a tenter and then continuously stretched by 4.0 times in a 100° C. heating zone in the width direction (TD direction) perpendicular to the longitudinal direction.

[Step 8]

Subsequently, the film was subjected to a heat treatment for 20 seconds at a temperature of 205° C. (first heat treatment temperature) in a heat treatment zone in the tenter. Subsequently, the film was relaxed at a relaxation ratio of 3% in the width direction (TD) at a temperature of 180° C., and by reducing the clip interval of the tenter, the film was relaxed at a relaxation ratio of 1.5% in the longitudinal direction (MD). Subsequently, the film was uniformly cooled to 25° C., and then was rolled. Thus, a biaxially stretched polyester film (PET-B) having a thickness of 250 μm was obtained.

The results of an evaluation of the characteristics of PET-B are presented below.
Content of terminal carboxyl groups: 30 eq/ton
Tmeta: 190° C.
Average elongation retention ratio: 2%
Plane orientation coefficient: 0.170
Intrinsic viscosity: 0.60 dl/g
Thermal shrinkage ratio (MD/TD): 0.4%/0.2%
Content of constituent component (p); none
Buffering agent: none
Terminal blocking agent: none

### Example 1

### Formation of Fluorine-Containing Polymer Layer

—Preparation of Coating Liquid A for Farming Fluorine-Containing Polymer Layer—

The various components of the following composition were mixed, and thus a coating liquid A for forming fluorine-containing polymer layer was prepared.

(Composition of Coating Liquid A)

| OBBLIGATO SW0011F | 49.5 | parts |
|---|---|---|
| (trade name, fluorine-based binder, manufactured by AGC | | |
| Coat-Tech Co., Ltd.; solids content: 39% by mass) | | |
| Carbodiimide compound (crosslinking agent) | 7.7 | parts |
| (trade name: CARBODILITE V-02-L2, manufactured by | | |
| Nisshinbo Holdings, Inc.; solids content: 25% by mass) | | |
| Polyoxyalkylene alkyl ether | 2 | parts |
| (trade name: NAROACTY CL95, manufactured by Sanyo | | |
| Chemical Industries, Ltd.; solids content: 1% by mass) | | |
| Distilled water | 40.8 | parts |

(Surface Treatment of Polyester Film Base Material)

An ITRO treatment was performed on both sides of the PET-1 under the following conditions.
Air supply rate: 154 L/mm
Gas supply rate; 7 L/min
ITRO treatment liquid: 1 L/mm
Transfer rate: 60 m/min
Distance between the flame and the surface: 20 mm

(Application of Fluorine-Containing Polymer Layer)

The thus obtained coating liquid A for forming fluorine-containing polymer layer was applied onto an ITRO-treated surface of the PET-1 in an amount of 3.0 g/m² in terms of the binder amount and then dried at 180° C. for 1 minute to form a fluorine-containing polymer layer (specific polymer layer) having a dry thickness of about 3 μm.

<Formation of Readily-Adhesive Layer>

—Preparation of Coating Liquid for Forming Readily-Adhesive Layer—

The various components of the following composition were mixed, and thus a coating liquid for forming readily-adhesive layer was prepared.

(Composition of Coating Liquid A)

| OBBLIGATO SW0011F | 3.2 | parts |
|---|---|---|
| (trade name, fluorine-based binder, manufactured by AGC | | |
| Coat-Tech Co., Ltd.; solids content: 39% by mass) | | |
| Polyoxyalkylene alkyl ether | 7.8 | parts |
| (trade name: NAROACTY CL95, manufactured by Sanyo | | |
| Chemical Industries, Ltd.; solids content: 1% by mass) | | |
| Oxazoline compound (crosslinking agent) | 0.8 | parts |
| (trade name: EPOCROS WS700, manufactured by Nippon | | |
| Shokubai Co., Ltd.; solids content: 25% by mass) | | |
| Water dispersion of sillica fine particles (trade name: AEROSIL | 2.9 | parts |
| OX-50, manufactured by NIPPON AEROSIL Co., Ltd.; volume | | |
| average particle diameter: 0.15μm, solids content: 10% by mass) | | |
| Distilled water | 85.3 | parts |

(Application of Coating Liquid for Forming Readily-Adhesive Layer)

The thus obtained coating liquid was applied in a binder amount of 0.09 g/m² onto the ITRO-treated surface of the PET-1 opposite to the one on which the fluorine-containing polymer layer was formed. The coating liquid was then dried at 180° C. for 1 minute to form a readily-adhesive layer (specific polymer layer).

<Formation of White Layer (Reflective Layer)>

(Preparation of Pigment Dispersion)

The components of the following composition were mixed, and the mixture was subjected to a dispersion treatment for one hour using a Dyno mill type dispersing machine.

—Composition of Pigment Dispersion—

| Titanium dioxide (volume average particle diameter = | 39.9% | by mass |
|---|---|---|
| 0.42 μm) (trade name: TIPAQUE R-780-2, | | |
| manufactured by Ishihara Sangyo | | |
| Kaisha, Ltd.; solid content: 100% by mass) | | |
| Polyvinyl alcohol | 8.0% | by mass |
| (trade name: PVA-105, manufactured by Kuraray Co., | | |
| Ltd.; solid content: 10% by mass) | | |
| Surfactant | 0.5% | by mass |
| (trade name: DEMOL EP, manufactured by Kao | | |
| Corporation; solid content: 25% by mass) | | |
| Distilled water | 51.6% | by mass |

(Preparation of Coating Liquid-1 for Reflective Layer)

The various components of the following composition were mixed, and thus a coating liquid-1 for reflective layer was prepared.

—Composition of coating liquid-1—

| Pigment dispersion obtained above | 80 | parts |
|---|---|---|
| OBBLIGATO SW0011F | 14.8 | parts |
| (trade name, fluorine-based binder, manufactured by AGC | | |
| Coat-Tech Co., Ltd.; solids content: 39% by mass) | | |
| Polyoxyalkylene alkyl ether | 3.0 | parts |
| (trade name: NAROACTY CL95, manufactured by | | |
| Sanyo Chemical Industries, Ltd.; solids content: 1% by mass) | | |
| Oxazoline compound (crosslinking agent) | 2.0 | parts |
| (trade name: EPOCROS WS700, manufactured by Nippon | | |
| Shokubai Co., Ltd.; solids content: 25% by mass) | | |
| Water dispersion of sillica fine particles | 2.9 | parts |
| trade name: AEROSIL OX-50, manufactured by | | |
| NIPPON AEROSIL Co., Ltd.; volume average particle diameter: | | |
| 0.15μm, solids content: 10% by mass) | | |
| Distilled water | 12.2 | parts |

(Application of Coating Liquid for Reflective Layer)

The coating liquid-1 for reflective layer thus obtained was applied on the readily-adhesive layer formed as described above, and the coating liquid was dried for one minute at 180° C. Thus, a white layer (a specific polymer layer) having an amount of titanium dioxide of 6.5 g/m²; as a reflective layer (a colored layer) was formed.

A layered product thus obtained was designated as a backsheet for a solar cell of Example 1.

### Example 2

A backsheet for a solar cell of Example 2 was produced in a manner substantially similar to that in Example 1, except that PET-1 in Example 1 was changed to PET-2.

### Example 3

A backsheet for a solar cell of Example 3 was produced in a manner substantially similar to that in Example 1, except that PET-1 in Example 1 was changed to PET-3.

### Example 4

A backsheet for a solar cell of Example 4 was produced in a manner substantially similar to that in Example 1, except that PET-1 in Example 1 was changed to PET-4.

### Example 5

A backsheet for a solar cell of Example 5 was produced in a manner substantially similar to that in Example 1, except that the carbodiimide compound (crosslinking agent) used in the preparation of the coating liquid A for forming fluorine-containing polymer layer in Example 1 was changed to the following oxazoline compound (crosslinking agent).
Oxazoline compound (crosslinking agent) (trade name: EPOCROS WS700, manufactured by Nippon Shokubai Co., Ltd.; solids content: 25% by mass)

### Example 6

A backsheet for a solar cell of Example 6 was produced in a manner substantially similar to, that in Example 1, except that the surface treatment performed on both sides of the PET-1 was changed to the below-described atmospheric-pressure plasma treatment (APP treatment).

Atmospheric-Pressure Plasma Treatment (APP Treatment)

While transferring the PET-1 in a plasma gas atmosphere in which an argon gas was mixed with air (gas pressure: 750 Torr), the PET-1 surface was irradiated for 15 seconds with a plasma having an output (discharge intensity) of 250 W-min/m², which was generated by electric discharge using a high-frequency discharge apparatus having a power-source frequency of 5 kHz.

### Example 7

A backsheet for a solar cell of Example 7 was produced in a manner substantially similar to that in Example 1, except that the PET-1 was not subjected to the surface treatment,

### Example 8

A backsheet for a solar cell of Example 8 was produced in a manner substantially similar to that in Example 1, except that the surface treatment performed on both sides of the PET-1 was changed to the below-described corona treatment.

Corona Treatment Conditions
Apparatus: solid-state corona treatment apparatus, Model 6 KVA; manufactured by Pillar Co.
Gap clearance between the electrode and the dielectric roll: 1.6 mm
Treatment frequency: 9.6 kHz
Treatment rate; 20 m/min
Treatment intensity: 0.375 kV-A·min/m².

### Example 9

A backsheet for a solar cell of Example 9 was produced in a manner substantially similar to that in Example 1, except that the coating liquid A for forming fluorine-containing polymer layer in Example 1 was changed to the following coating liquid B for forming fluorine-containing polymer layer.

—Composition of Coating Liquid B—

| OBBLIGATO SW0011F | 49.5 | parts |
|---|---|---|
| (trade name, fluorine-based binder, manufactured | | |
| by AGC Coat-Tech Co., Ltd.; | | |
| solids content: 39% by mass) | | |
| Carbodiimide compound (crosslinking agent) | 7.7 | parts |
| (trade name: CARBODILITE V-02-L2, manufactured by | | |
| Nisshinbo Holdings, Inc.; solids content: 25% by mass) | | |
| Polyoxyalkylene alkyl ether | 2 | parts |
| (trade name: NAROACTY CL95, manufactured by Sanyo | | |
| Chemical Industries; Ltd.; solids content: 1% by mass) | | |
| Dispersion liquid of white pigment prepared in the following | | |
| procedure 33 parts | | |
| Distilled water | 7.8 | parts |

(Preparation of White Pigment Dispersion)

The components of the following composition were mixed, and the mixture was subjected to a dispersion treatment for one hour using a Dyno mill type dispersing machine.

—Composition of White Pigment Dispersion—

| | |
|---|---|
| Titanium dioxide (volume average particle diameter = | 39.9% by mass |
| 0.42 μm) (trade name: TIPAQUE R-780-2, manufactured by | |
| Ishihara Sangyo Kaisha, Ltd.; solid content: 100% by mass) | |
| Polyvinyl alcohol | 8.0% by mass |
| (trade name: PVA-105, manufactured by Kuraray Co., Ltd.; | |
| solid content: 10% by mass) | |
| Surfactant | 0.5% by mass |
| (trade name: DEMOL EP, manufactured by Kao | |
| Corporation; solid content: 25% by mass) | |
| Distilled water | 51.6% by mass |

### Comparative Example 1

A backsheet for a solar cell of Comparative Example 1 was produced in a manner substantially similar to that in Example 1, except that PET-1 in Example 1 was changed to PET-A.

### Comparative Example 2

A backsheet for a solar cell of Comparative Example 2 was produced in a manner substantially similar to that in Example 1, except that PET-1 in Example 1 was changed to PET-B

### Comparative Example 3

A backsheet for a solar cell of Comparative Example 3 was produced in a manner substantially similar to that in Example 1, except that each of OBBLIGATO SW0011F used in each preparation of the coating liquid A for forming fluorine-containing polymer layer, the coating liquid for readily-adhesive layer and the coating liquid-1 for reflective layer in Example 1 was replaced with OLESTER UD350 (trade name, manufactured by MITSUI CHEMICALS Inc., polyurethane resin, it may be also referred as “PU” hereafter.) in preparation of each coating liquid, and each layer thereof was respectively formed by using the coating liquid thus obtained,

### Comparative Example 4

A backsheet for a solar cell of Comparative Example 4 was produced in a manner substantially similar to that in Example 1, except that the carbodiimide compound used in the preparation of the coating liquid A for forming fluorine-containing polymer layer, and the oxazoline compound used in the preparation of the coating liquid for readily-adhesive layer and the coating liquid-1 for reflective layer in Example 1 was respectively replaced with epoxy compound (manufactured by NAGASE CHEMTEX Co.; solid content 25%) as a crosslinking agent in preparation of each coating liquid, and each layer thereof was respectively formed by using the coating liquid thus obtained.

### Comparative Example 5

A backsheet for a solar cell of Comparative Example 5 was produced in a manner substantially similar to that in Example 1, except that a crosslinking agent in each preparation of the coating liquid A for forming fluorine-containing polymer layer, the coating liquid for readily-adhesive layer and the coating liquid-1 for reflective layer in Example 1, was not used in Comparative Example 5.

### Comparative Example 6

A backsheet for a solar cell of Comparative Example 6 was produced in a manner substantially similar to that in Comparative Example 5, except that the surface treatment to PET-1 was not applied in Comparative Example 6.

[Evaluation Method]

(1) Retention Rate of Breaking Elongation

Samples A and B for measurement were prepared by cutting samples to a size of 10 mm in width×200 mm in length.

Sample A was humidified for 24 hours in an atmosphere at 25° C. and 60% RH, and then was subjected to a tensile test with a Tensilon (trade name: RTC-1210A, manufactured by Orientec Co., Ltd.). The length of the sample to be stretched was 10 cm, and the tensile rate was 20 mm/min. The breaking elongation of the sample A obtained by this evaluation was designated as L0.

Separately, sample B was subjected to a heat and moisture treatment for 3000 hours in an atmosphere of 85° C. and 85% RH, and then was subjected to a tensile test in the same manner as in the case of the sample A. The breaking elongation of the sample B in this case was designated as L1.

The retention rate of breaking elongation (Lrb) (%) represented by the following formula was calculated for the samples thus obtained, based on the measurement values, L0 and L1, of breaking elongation obtained by the measurement method described above.

Lrb(%)=L1/L0×100

A retention rate of breaking elongation of 50% or greater was considered acceptable in terms of practical use.

(2) Adhesiveness Before a Lapse of Time Under Heat and Moisture

The surface of the fluorine-containing polymer layer of a sample was cut with a single-blade razor, 6 lines each in the length and width directions at an interval of 3 mm, and thus 25-mesh grids were formed. A Mylar tape (polyester adhesive tape) was attached thereon, and the tape was peeled by pulling manually in the 180° C. direction along the sample surface. At this time, the number of peeled mesh grids was counted, and thereby the adhesive force of the polymer layer was rated according to the following evaluation criteria. Evaluation grades 4 and 5 are considered acceptable in terms of practical use.

<Evaluation Criteria>

5: There are no peeled mesh grids (0 meshes).

4: The number of peeled mesh grids is from 0 to less than 0.5.

3: The number of peeled mesh grids is from 0.5 to less than 2.

2: The number of peeled mesh grids is from 2 to less than 10.

1: The number of peeled mesh grids is 10 or larger.

(3) Adhesiveness after a Lapse of Time Under Heat and Moisture

A sample was maintained in an environment of 85° C. and 85% RH for 3000 hours, and then was humidified for one hour in an environment of 25° C. and 60% RH. Thereafter, the adhesive force of the fluorine-containing polymer layer was evaluated by the same method as that used in the evaluation of “(2) Adhesiveness before a lapse of time under heat and moisture”. Evaluation grades 3, 4 and 5 are considered acceptable in terms of practical use.

(4) Adhesion after Irradiation with Ultraviolet Light (UV)

Using a super-high energy irradiation tester (Model UE-1DEc) manufactured by Suga Test Instruments Co., Ltd., the thus obtained backsheet for a solar cell was irradiated for 48 hours with a light which shows a peak in the ultraviolet wavelength region and has an energy of 100 mW/cm². Immediately thereafter, the adhesive force of the back layer was evaluated by the same method used for the above-described evaluation of “(2) Adhesion before a lapse of time under heat and moisture”.

Here, the temperature of the backsheet during the light irradiation was controlled to be 63° C.

The evaluation grades of 3, 4 and 5 fall in the practically acceptable range.

The results of evaluating the retention rate of breaking elongation, the adhesion before a lapse of time under heat and moisture, the adhesion after a lapse time of under heat and moisture and the adhesion after irradiation with ultraviolet light (UV) for the respective backsheets for a solar cell according to Examples and Comparative Examples are shown in Tables 1 and 2 below.

As the polymer layers in Tables 1 and 2 below, among those polymer layers formed in the above, a specific polymer layer or a comparative polymer layer, which was formed by using the coating liquid A for forming fluorine-containing polymer layer, the coating liquid for comparison with the coating liquid A (Comparative Example 5) or the coating liquid B for forming fluorine-containing polymer layer, is shown.

TABLE 1

| | | | Exp. 1 | Exp. 2 | Exp. 3 | Exp. 4 | Exp. 5 | Exp. 6 | Exp. 7 | Exp. 8 | Exp. 9 |
|---|---|---|---|---|---|---|---|---|---|---|---|
| Base material | Kind of PET | — | PET-1 | PET-2 | PET-3 | PET-4 | PET-1 | PET-1 | PET-1 | PET-1 | PET-1 |
| | Carboxyl group content | eq/t | 5 | 7 | 5 | 12 | 5 | 5 | 5 | 5 | 5 |
| | Tmeta | ° C. | 190 | 180 | 190 | 190 | 190 | 190 | 190 | 190 | 190 |
| | Average elongation retention ratio | % | 50 | 35 | 40 | 25 | 50 | 50 | 50 | 50 | 50 |
| | Amount of component (p) | mole % | 0.15 | none | 0.15 | 0.15 | 0.15 | 0.15 | 0.15 | 0.15 | 0.15 |
| | Amount of buffer agent | mole/t | 1.5 | 1.5 | none | 1.5 | 1.5 | 1.5 | 1.5 | 1.5 | 1.5 |
| | Amount of terminal sealing material | mass % | 1 | 1 | 1 | none | 1 | 1 | 1 | 1 | 1 |
| | Kind of terminal sealing material | — | CDI | CDI | CDI | none | CDI | CDI | CDI | CDI | CDI |
| | Phosphorus element content | ppm | 230 | 230 | 150 | 230 | 230 | 230 | 230 | 230 | 230 |
| | Surface treatment | — | ITRO | ITRO | ITRO | ITRO | ITRO | APP | none | Corona | ITRO |
| Poly. L. | Kind of polymer | — | FCP | FCP | FCP | FCP | FCP | FCP | FCP | FCP | FCP |
| | Kind of crosslinking agent | — | CDI | CDI | CDI | CDI | CDI | CDI | CDI | CDI | CDI |
| | White pigment | — | none | none | none | none | none | none | none | none | present |
| Evaluation | Retention rate of breaking elongation | | 80% | 65% | 70% | 50% | 80% | 80% | 80% | 80% | 80% |
| | A.B.L.T.H.M | | 5 | 5 | 5 | 5 | 5 | 5 | 5 | 5 | 5 |
| | A.A.L.T.H.M. | | 5 | 5 | 5 | 5 | 5 | 5 | 3 | 4 | 5 |
| | A.A.I.U.V. | | 4 | 4 | 4 | 4 | 4 | 4 | 4 | 4 | 5 |

TABLE 2

| | | | Comp. | Comp. | Comp. | Comp. | Comp. | Comp. |
|---|---|---|---|---|---|---|---|---|
| | | | Exp. 1 | Exp. 2 | Exp. 3 | Exp. 4 | Exp. 5 | Exp. 6 |
| Base material | Kind of PET | — | PET-A | PET-B | PET-1 | PET-1 | PET-1 | PET-1 |
| | Carboxyl group content | eq/t | 5 | 30 | 5 | 5 | 5 | 5 |
| | Tmeta | ° C. | 225 | 190 | 190 | 190 | 190 | 190 |
| | Average elongation retention ratio | % | 7 | 2 | 50 | 50 | 50 | 50 |
| | Amount of component (p) | mole % | 0.15 | none | 0.15 | 0.15 | 0.15 | 0.15 |
| | Amount of buffer agent | mole/t | 1.5 | none | 1.5 | 1.5 | 1.5 | 1.5 |
| | Amount of terminal sealing material | mass % | 1 | none | 1 | 1 | 1 | 1 |
| | Kind of terminal sealing material | — | CDI | none | CDI | CDI | CDI | CDI |
| | Phosphorus element content | ppm | 230 | none | 230 | 230 | 230 | 230 |
| | Surface treatment | — | ITRO | ITRO | ITRO | ITRO | ITRO | none |
| Poly. | Kind of polymer | — | FCP | FCP | PU | FCP | FCP | FCP |
| L. | Kind of crosslinking agent | — | CDI | CDI | CDI | Epoxy | none | none |
| Evaluation | Retention rate of breaking elongation | | 10% | 0% | 80% | 80% | 80% | 70% |
| | A.B.L.T.H.M. | | 5 | 5 | 5 | 3 | 2 | 1 |
| | A.A.L.T.H.M. | | 2 | 2 | 1 | 1 | 1 | 1 |
| | A.A.I.U.V. | | 4 | 4 | 2 | 2 | 1 | 1 |

In Tables 1 and 2, the abbreviation “Poly. L.” denotes “Polymer layer”, the abbreviation “Exp.” denotes “Example number”, the abbreviation “Comp, Exp.” denotes “Comparative Example number”, the abbreviation “CDI” denotes “Carbodiimide”, the abbreviation “APP” denotes “Atmospheric-pressure plasma treatment”, the abbreviation “FCP” denotes “Fluorocarbon based polymer”, the abbreviation “PU” denotes “polyurethane resin”, the abbreviation “A.B.L.T.H.M.” denotes “Adhesiveness before a lapse of time under heat and moisture”, the abbreviation “A.A.L.T.H.M.” denotes “Adhesiveness after a lapse of time under heat and moisture”, and the abbreviation “A.A.I.U.V.” denotes “Adhesion after irradiation with ultraviolet light”.

From Tables 1 and 2, as compared to those backsheets for a solar cell according to Comparative Examples, the backsheets for a solar cell according to Examples were found to be superior in all of the retention rate of breaking elongation, the adhesion before and after a lapse of time under heat and moisture and the adhesion after irradiation with ultraviolet light (UV).

### Example 10

A 3 mm-thick tempered glass, an EVA sheet (SC50B, manufactured by Mitsui Chemical Fabro, Inc.), a photovoltaic cell, an EVA sheet (SC50B, manufactured by Mitsui Chemical Fabro, Inc.) and the backsheet for a solar cell obtained in Example 1 were laminated in this order and hot-pressed using a vacuum laminator (manufactured by Nisshinbo Holdings, Inc.), thereby adhering the tempered glass, the photovoltaic cell and the backsheet with the respective EVA sheets. Here, the backsheet was arranged such that the reflective layer thereof was in contact with the EVA sheet.

The EVA adhesion conditions were as follows.

After subjecting the laminated materials to vacuuming at 128° C. for 3 minutes using a vacuum laminator, the resulting laminate was pressured for 2 minutes to perform preliminary adhesion. Then, a main adhesion treatment was performed in a drying oven at 150° C. for 30 minutes.

In the above-described manner, a crystalline solar cell module was produced. When the thus obtained solar cell module was operated to generate electricity, the solar cell module showed good power generation performance as a solar cell.

### Examples 11 to 18

A crystalline solar cell module was produced in a manner substantially similar to that in Example 10, except that the backsheet for a solar cell used in Example 10 was changed to the respective backsheets for a solar cell that were produced in Examples 2 to 9.

The thus obtained solar cell, modules of Examples 11 to 18 all showed good power generation performance as a solar cell.

The foregoing description of the exemplary embodiments of the present invention has been provided for the purposes of illustration and description. It is not intended to be exhaustive or to limit the invention to the precise forms disclosed. The embodiments were chosen and described in order to best explain the principles of the invention and its practical applications, thereby enabling others skilled in the art to understand the invention for various embodiments and with the various modifications as are suited to the particular use contemplated.

This application claims priority from Japanese Patent Application No. 2011-068809 filed on Mar. 25, 2011, the disclosure of which is incorporated by reference herein. All publications, patent applications, and technical standards mentioned in this specification are herein incorporated by reference to the same extent as if such individual publication, patent application, or technical standard was specifically and individually indicated to be incorporated by reference. It will be obvious to those having skill in the art that many changes may be made in the above-described details of the preferred embodiments of the present invention. It is intended that the scope of the invention be defined by the following claims and their equivalents.

What is claimed is:

1. A solar cell backsheet, which is arranged in contact with a sealing material of a cell-side substrate on which a photovoltaic element is sealed with the sealing material,
the solar cell backsheet comprising a polyester film base material and at least one polymer layer arranged thereon,
wherein the polyester film base material has a carboxyl group content of from 1 eq/ton to 15 eq/ton, a minute endothermic peak temperature Tmeta (° C.) of 220° C. or lower as determined by differential scanning calorimetry, and an average elongation retention ratio of 10% or more as determined after being left to stand for 72 hours under conditions of a temperature of 125° C. and a relative humidity of 100% RH; and
the at least one polymer layer comprises at least a fluorocarbon-based polymer, has a crosslinked structure derived from at least one crosslinking agent selected from the group consisting of carbodiimide-based compounds and oxazoline-based compounds, and is formed by coating.

2. The solar cell backsheet according to claim 1, wherein the polyester film base material comprises a polyester containing a constituent component of dicarboxylic acid, a constituent component of a diol and a constituent component (p) in which a sum of a number of carboxyl groups (a) and a number of hydroxy 1 groups (b) (a+b) is 3 or greater, and a content of the constituent component (p) is in a range of from 0.005% by mole to 2.5% by mole with respect to a total amount of constituent components contained in the polyester.

3. The solar cell backsheet according to claim 1, wherein the polyester film base material comprises a buffer agent in a range of from 0.1 mol/ton to 5.0 mol/ton with respect to a total mass of the polyester contained in the polyester film base material.

4. The solar cell backsheet according to claim 1, wherein the polyester film base material comprises a terminal blocking agent which is a carbodiimide compound, in a range of from 0.1% by mass to 5% by mass with respect to a total mass of the polyester contained in the polyester film base material.

5. The solar cell backsheet according to claim 1, wherein a content of phosphorus atoms determined by a fluorescent X-ray analysis of the polyester film base material is 200 ppm or greater.

6. The solar cell backsheet according to claim 1, wherein the polyester film base material is subjected to a surface treatment.

7. The solar cell backsheet according to claim 6, wherein the surface treatment is at least one surface treatment selected from the group consisting of a flame treatment in which flame is applied together with a silane compound and atmospheric pressure plasma treatment.

8. The solar cell backsheet according to claim 6, wherein the at least one polymer layer comprising at least a fluorocarbon-based polymer and a crosslinked structure derived from at least one crosslinking agent selected from the group consisting of carbodiimide-based compounds and oxazoline-based compounds, directly contacts a surface of the polyester film base material subjected to a surface treatment.

9. The solar cell backsheet according to claim 1, wherein the at least one polymer layer comprising at least a fluorocarbon-based polymer and a crosslinked structure derived from at least one crosslinking agent selected from the group consisting of carbodiimide-based compounds and oxazoline-based compounds is an outermost layer.

10. The solar cell backsheet according to claim 1, wherein the at least one polymer layer is a reflective layer feat reflects light and comprises a white pigment.

11. A method of forming a solar cell backsheet, the method comprising:
applying a coating liquid comprising at least a fluorocarbon-based polymer and at least one crosslinking agent selected from the group consisting of carbodiimide-based compounds and oxazoline-based compounds, onto a polyester film base material having a carboxyl group content of from 1 eq/ton to 15 eq/ton, a minute endothermic peak temperature Tmeta (° C.) of 220° C. or lower as determined by differential scanning calorimetry, and an average elongation retention ratio of 10% or more as determined after being left to stand for 72 hours under conditions of a temperature of 125° C. and a relative humidity of 100% RH.

12. The method of forming a solar cell backsheet according to claim 11, the method further comprising:
applying, to a surface side of the polyester film base material that is coated with the coating liquid, at least one surface treatment selected from the group consisting of a flame treatment in which flame is applied together with a silane compound and atmospheric pressure plasma treatment.

13. The method of forming a solar cell backsheet according to claim 11, wherein the coating liquid further comprises a solvent, and 50% by mass or greater of the solvent is water.

14. A solar cell module, comprising the solar cell backsheet according to claim 1.

15. The solar cell module according to claim 14, further comprising:
a transparent front base board through which sunlight enters;
a cell structural portion that is provided on the front base board and comprises a solar cell element and a sealing material that seals the solar cell element; and
at least one solar cell backsheet as provided at the solar cell module according to claim 14, the solar cell backsheet being provided on a side of the cell structural portion opposite to a side at which the front base board is placed, so as to be adjacent to the sealing material.

16. The solar cell backsheet according to claim 2, wherein the polyester film base material comprises:
a buffer agent in a range of from 0.1 mol/ton to 5.0 mol/ton with respect to a total mass of the polyester contained in the polyester film base material; and
a terminal blocking agent, which is a carbodiimide compound, in a range of from 0.1% by mass to 5% by mass with respect to a total mass of the polyester contained in the polyester film base material, and
a content of phosphorus atoms determined by a fluorescent X-ray analysis of the polyester film base material is 200 ppm or greater.

17. The solar cell backsheet according to claim 16, wherein the polyester film base material is subjected to a surface treatment, the surface treatment being at least one surface treatment selected from the group consisting of a flame treatment in which flame is applied together with a silane compound and atmospheric pressure plasma treatment.

18. The solar cell backsheet according to claim 17, wherein the at least one polymer layer comprising at least a fluorocarbon-based polymer and a crosslinked structure derived from at least one crosslinking agent selected from the group consisting of carbodiimide-based compounds and oxazoline-based compounds, directly contacts a surface of the polyester film, base material subjected to a surface treatment, or is an outermost layer.
